(19) United States
(12) Patent Application Publication
(10) Pub. No.: US 2014/0212087 A1
(43) Pub. Date: Jul. 31, 2014

(54) SEMICONDUCTOR APPARATUS INCLUDING AN OPTICAL DEVICE AND AN ELECTRONIC DEVICE, AND METHOD OF MANUFACTURING THE SAME

(71) Applicant: Samsung Electronics Co., Ltd, Suwon-si (KR)

(72) Inventors: Kwan-Sik CHO, Hwaseong-si (KR); Jung-Hye KIM, Seoul (KR); Yong-Hwack SHIN, Hwaseong-si (KR)

(73) Assignee: Samsung Electronics Co., Ltd, Suwon-si (KR)

(21) Appl. No.: 14/163,069

(22) Filed: Jan. 24, 2014

(30) Foreign Application Priority Data
Jan. 25, 2013 (KR) 10-2013-0008328

(51) Int. Cl. G02B 6/136

(52) U.S. Cl. CPC G02B 6/136
USPC 385/14; 438/31

(57) ABSTRACT

A method of manufacturing a semiconductor apparatus includes forming a gate structure and an etch stop layer structure on a substrate including first and second regions. The gate structure is formed in the first region, and the etch stop layer structure is formed in the second region. A first insulating interlayer is formed on the substrate to cover the gate structure and the etch stop layer structure. The first insulating interlayer is partially removed to expose the etch stop layer structure. The exposed etch stop layer is removed to expose the substrate. An optical device is formed on the exposed substrate.

### CROSS-REFERENCE TO RELATED APPLICATIONS

This application claims priority under 35 USC §119 to Korean Patent Application No. 10-2013-0008328, filed on Jan. 25, 2013 in the Korean Intellectual Property Office (KIPO), the contents of which are herein incorporated by reference in their entirety.

### BACKGROUND

1. Field

The present general inventive concept relates to a semiconductor apparatus including an optical device and an electronic device, and a method of manufacturing the same.

2. Description of the Related Art

Semiconductor manufacturing technologies have been improved in strength, durability, and performance. A semiconductor device with many integrated circuits connecting electrically cannot operate at its maximum performance of data transfer due to inherent and practical limitations of electrical communications.

As enhancement of the data transfer speed through electrical integrated circuits reaches a limit, combining optical integrated circuits and electrical integrated circuits onto a same bulk substrate of silicon or similar materials has been developed.

Manufacturing semiconductors containing both optical devices and electronic devices on a same substrate faces many practical obstacles. A planarization process and other processing steps used in forming the electrical device may easily cause damage to the optical device subsequently to be formed on the same substrate. Various types of damage to the substrate causing less than desired crystalline characteristics further induces defects in functionality of the optical devices formed thereon. Thus, when forming the electronic devices, the bulk silicon substrate from which the optical devices may be formed has to be protected.

### SUMMARY

Exemplary embodiments of the present general inventive concept provide a device and method to support a semiconductor apparatus including an optical device and an electronic device.

Additional features and utilities of the present general inventive concept will be set forth in part in the description which follows and, in part, will be obvious from the description, or may be learned by practice of the general inventive concept.

The foregoing features and/or utilities of the present general inventive concept may be achieved by providing a method of manufacturing a semiconductor apparatus on a substrate containing a first region and a second region. The method includes forming a gate structure in the first region of the substrate, and forming an etch stop layer structure in the second region of the substrate, followed by forming a first insulating interlayer on the substrate to cover the gate structure and the etch stop layer structure. The first insulating interlayer is then partially removed to expose the etch stop layer structure; and the exposed etch stop layer is removed to expose the substrate in the second region, where an optical device is formed.

When the gate structure and the etch stop layer structure are formed, an insulation layer and a first conductive layer may be sequentially formed on the substrate including the first region and the second region. A second etch stop layer pattern may be formed on the first conductive layer in the second region of the substrate. A mask may be formed on the first conductive layer in the first region of the substrate. The first conductive layer and the insulation layer may be patterned using the mask as an etching mask to form the gate structure and the etch stop layer structure. The gate structure may include a gate insulation layer pattern, a gate electrode and the mask sequentially stacked on the substrate in the first region. The etch stop layer structure may include an insulation layer pattern, a first etch stop layer pattern, and the second etch stop layer pattern sequentially stacked on the substrate in the second region.

When the exposed etch stop layer is removed, the first insulating interlayer may be partially removed to expose the second etch stop layer pattern. The exposed second etch stop layer pattern, the first etch stop layer pattern, and the insulation layer pattern under the exposed second etch stop layer pattern may be removed to expose the substrate underneath.

A second conductive layer structure may be further formed on the first conductive layer and the second etch stop layer pattern before forming the mask. The mask may be formed on the second conductive layer structure. When the gate structure is formed in the first region of the substrate, the second conductive layer structure, the first conductive layer, and the insulation layer may be patterned using the mask as an etching mask.

The first conductive layer may be formed to include doped polysilicon, and the second conductive layer structure may be formed to include a barrier layer and a metal layer sequentially stacked.

The second etch stop layer pattern may be formed to include a material having an etch selectivity with respect to the first conductive layer.

The first conductive layer may be formed to include doped polysilicon, and the second etch stop layer pattern may be formed to include silicon oxide.

The first insulating interlayer and the insulation layer may be formed to include silicon oxide.

The first conductive layer may be formed to include a material having an etch selectivity with respect to the first insulating interlayer and the insulation layer.

The second etch stop layer pattern may be formed to include a material substantially the same as that of the insulation layer, and may have a thickness equal to or greater than that of the insulation layer.

An isolation layer pattern may be further formed on the substrate in the second region before forming the insulation layer and the first conductive layer on the substrate. When the exposed second etch stop layer pattern, the first etch stop layer pattern, and the insulation layer pattern under the exposed second etch stop layer pattern are removed, the isolation layer pattern and a portion of the substrate adjacent to the isolation layer pattern may be exposed.

When the optical device is formed, an epitaxial growth process may be performed using the exposed substrate as a seed.

When the optical device is formed, the epitaxial growth process may be performed to form a semiconductor layer. The semiconductor layer may be patterned to form a core partially exposing the isolation layer pattern. A second insulating interlayer may be formed to cover the core. The isolation layer pattern and the second insulating interlayer may serve as a cladding surrounding the core, so that the core and the cladding may form a light waveguide.

A semiconductor apparatus may be formed on a substrate including a first region and a second region, such that a gate structure is formed on the first region, and an optical device is formed on the second region. The gate structure includes a gate insulation layer pattern, a gate electrode, and a mask, sequentially stacked on the substrate in the first region. On the same substrate including the first and second regions, an insulation layer pattern and an etch stop layer pattern are sequentially stacked on the substrate adjacent to and spaced apart from the optical device in the second region of the substrate. The gate insulation layer pattern and the insulation layer pattern include substantially the same material, and the gate electrode and the etch stop layer pattern include substantially the same material. The electrical device and the optical device are formed such that formation of the electrical device incurs reduced damage to formation of the optical device through controlled measures.

The gate electrode may further include a doped polysilicon layer, a barrier layer and a metal layer sequentially stacked. The etch stop layer pattern may include doped polysilicon. The gate insulation layer pattern and the insulation layer pattern may include silicon oxide.

According to example embodiments, an electronic device including the gate structure may be first formed in the first region of the substrate, and an optical device including the semiconductor pattern may be subsequently formed in the second region of the substrate, where damage to the substrate is prevented via controlled measures.

In some cases, size of the electronic device may be relatively larger than that of the optical device, so that a planarization process on the insulating interlayer covering the electronic device may cause none or less damage to the optical devices.

Additionally, the electronic device may be formed through a heat treatment process, so that the physical characteristics of silicon substrate supporting the optical device may not be changed.

Furthermore an etch stop layer pattern having a high etch selectivity with respect to the insulating interlayer may be formed on the substrate to prevent etching damages to the substrate in the subsequent steps to form the optical device. Thus using the single crystalline semiconductor material contained in the above substrate as a seed, the optical device with a desired functionality may be further formed.

A semiconductor apparatus comprises a substrate having at least a first region and a second region, an electrical device disposed in the first region, an optical device disposed in the second region, and an etch stop layer structure disposed in the second region apart from the optical device.

The electrical device in the semiconductor apparatus comprises a gate structure and the optical device comprises a core and a cladding.

The core, the gate structure and the etch stop layer structure of the semiconductor apparatus are all disposed on the substrate.

The cladding in the semiconductor apparatus comprises an isolation layer pattern disposed between the core and the substrate and an insulating interlayer to surround portions of the core not in contact with the isolation layer pattern.

The etch stop layer structure of the semiconductor apparatus comprises an insulation layer pattern disposed on the substrate, a first etch stop layer disposed on the insulation layer pattern, and a second etch stop layer disposed on the insulation layer pattern.

### BRIEF DESCRIPTION OF THE DRAWINGS

These and/or other features and utilities of the present general inventive concept will become apparent and more readily appreciated from the following description of the embodiments, taken in conjunction with the accompanying drawings of which:

FIG. 1 is a plan view illustrating a semiconductor apparatus in accordance with an exemplary embodiment of the present general inventive concept;

FIG. 2 is a cross-sectional view of the semiconductor apparatus cut along a line I-I′ of FIG. 1;

FIGS. 3 through 12 are cross-sectional views illustrating stages of manufacturing a semiconductor apparatus in accordance with an exemplary embodiment of the present general inventive concept;

FIG. 13 is a cross-sectional view illustrating a semiconductor apparatus in accordance with an exemplary embodiment of the present general inventive concept;

FIGS. 14 through 16 are cross-sectional views illustrating stages of manufacturing a semiconductor apparatus in accordance with an exemplary embodiment of the present general inventive concept;

FIG. 17 is a cross-sectional view illustrating a semiconductor apparatus in accordance with an exemplary embodiment of the present general inventive concept;

FIGS. 18 through 23 are cross-sectional views illustrating stages of manufacturing a semiconductor apparatus in accordance with an exemplary embodiment of the present general inventive concept;

FIG. 24 is a plan view illustrating a semiconductor apparatus in accordance with an exemplary embodiment of the present general inventive concept;

FIG. 25 is a cross-sectional view of the semiconductor apparatus cut along a line II-II′ of FIG. 24;

FIGS. 26 through 32 are cross-sectional views illustrating stages of manufacturing a semiconductor apparatus in accordance with an exemplary embodiment of the present general inventive concept;

FIG. 33 is a plan view illustrating a semiconductor apparatus in accordance with an exemplary embodiment of the present general inventive concept; and

FIG. 34 is a cross-sectional view of the semiconductor apparatus cut along a line III-III′ of FIG. 33.

### DETAILED DESCRIPTION OF THE EMBODIMENTS

Reference will now be made in detail to the embodiments of the present general inventive concept, examples of which are illustrated in the accompanying drawings, wherein like reference numerals refer to the like elements throughout. The embodiments of the present general inventive concept are described below in order to explain the present general inventive concept while referring to the figures.

It will be understood that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will also be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments of the present general inventive concept only and is not intended to be limiting of the present inventive concept. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present general inventive concept are described herein with reference to cross-sectional illustrations that are schematic illustrations of idealized example embodiments (and intermediate structures) of the present general inventive concept. As such, variations from the shapes of the illustrations as a result, for example, of manufacturing techniques and/or tolerances, are to be expected. Thus, example embodiments of the present general inventive concept should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which the present general inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Example embodiments of the present general inventive concept will be described below with reference to the accompanying drawings.

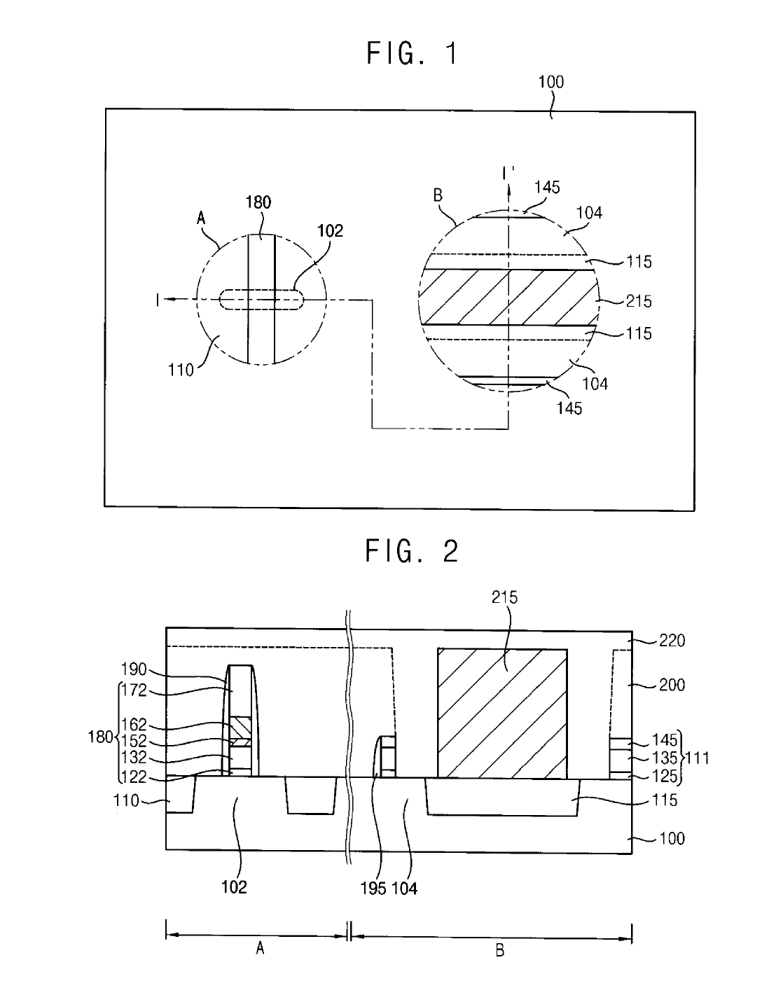

FIG. 1 is a plan view illustrating a semiconductor apparatus in accordance with an exemplary embodiment of the present general inventive concept, and FIG. 2 is a cross-sectional view of the semiconductor apparatus cut along the line I-I′ of FIG. 1. For the convenience of explanation, some elements of a conventional semiconductor apparatus are not illustrated in FIG. 1.

Referring to FIGS. 1 and 2, the semiconductor apparatus may include a first gate structure 180, a first semiconductor pattern 215, and a first etch stop layer structure 111 on a substrate 100. The semiconductor apparatus may further include a first insulating interlayer 200 and a second insulating interlayer 220.

The substrate 100 may include a semiconductor material, such as silicon, germanium, silicon-on-insulator (SOI) substrate, or a germanium-on-insulator (GOI) substrate, but is not limited thereto.

The substrate 100 may include first and second regions A and B, respectively. As illustrated in FIG. 1, the first region A may be an electronic device region, and the second region B may be an optical device region.

First and second isolation layer patterns 110 and 115, respectively, may be formed on the substrate 100. The first isolation layer pattern 110 may be formed in the first region A, and the second isolation layer pattern 115 may be formed in the second region B.

The substrate 100 may be divided into active regions and field regions by the first isolation layer pattern 110 and second isolation layer pattern 115. The active regions are the regions where neither of the first isolation layer pattern 110 nor the second isolation layer pattern115 is formed, and the field regions are the regions where at least one of the first isolation layer pattern 110 or the second isolation layer pattern 115 is formed. Particularly, a first active region 102 is located in the first region A of the substrate 100, and a second active region 104 is located in the second region B of the substrate 100. The first isolation layer pattern 110 and the second isolation layer pattern 115 may include an insulating material such as silicon oxide, but is not limited thereto.

The first gate structure 180 may include a gate insulation layer pattern 122, a first gate electrode, and a mask 172 sequentially stacked on the substrate 100 in the first region A. The first gate electrode may also include a gate conductive layer pattern 132, a barrier layer pattern 152, and a gate metal layer pattern 162 sequentially stacked on the gate insulation layer pattern 122. In some cases, the barrier layer pattern 152 may not be formed.

The gate insulation layer pattern 122 may include silicon oxide, and the gate conductive layer pattern 132 may include doped polysilicon, but neither is limited thereto. The barrier layer pattern 152 may include a metal nitride, such as titanium nitride, tantalum nitride, tungsten nitride, and the gate metal layer pattern 162 may include a metal, such as tungsten, titanium, tantalum, and copper, but neither is limited thereto.

A first spacer 190 may be further formed on a sidewall of the first gate structure 180. The first spacer 190 may include silicon nitride, but neither is limited thereto.

An impurity region (not illustrated) may be further formed at an upper portion of the substrate 100 adjacent to the first gate structure 180.

The first semiconductor pattern 215 may be formed on the second isolation layer pattern 115 in the second region B of the substrate 100. The first semiconductor pattern 215 may be formed in a center position on a top portion of the second isolation layer pattern 115, without covering edges of the second isolation layer pattern 115.

The first semiconductor pattern 215 may include single crystalline silicon or single crystalline germanium, but is not limited thereto.

The first etch stop layer structure 111 may include an insulation layer pattern 125, a first etch stop layer pattern 135 and a second etch stop layer pattern 145 sequentially stacked on the substrate 100 in the second region B. In some cases, the first etch stop layer structure 111 may not include the second etch stop layer pattern 145. The first etch stop layer structure 111 may be formed on a top surface of the substrate 100 adjacent to the second isolation layer pattern 115, on which the first semiconductor pattern 215 is formed, and may be spaced apart from the first semiconductor pattern 215.

The insulation layer pattern 125 may include a material substantially the same as that used in forming the gate insulation layer pattern 122, such as silicon oxide, but is not limited thereto.

The first etch stop layer pattern 135 may include a material substantially the same as that used in forming the gate conductive layer pattern 132, such as doped polysilicon, but is not limited thereto.

The second etch stop layer pattern 145 may include a material having a high etch selectivity with respect to the first etch stop layer pattern 135, such as silicon oxide or silicon nitride, but is not limited thereto.

A second spacer 195 may be further formed on a sidewall of the first etch stop layer structure 111.

The first insulating interlayer 200 may be formed on the substrate 100, and thus may cover portions of the substrate 100, the first gate structure 180, the first spacer 190, and the first etch stop layer structure 111. The first insulating interlayer 200 may include silicon oxide, but is not limited thereto.

The second insulating interlayer 220 may be formed on the substrate 100, thus may cover different portions of the substrate 100, the first semiconductor pattern 215, the second isolation layer pattern 115, and the first insulating interlayer 200. The second insulating interlayer 220 may include silicon oxide, but is not limited thereto.

In example embodiments of the present general inventive concept, the first semiconductor pattern 215, and the second insulating interlayer 220 and the second isolation layer pattern 115 surrounding the first semiconductor pattern 215 may form a light waveguide. In the light waveguide, the first semiconductor pattern 215 may serve as a core, and the second insulating interlayer 220 and the second isolation layer pattern 115 may serve as a cladding.

The first semiconductor pattern 215 may include a semiconductor material that may be formed by an epitaxial growth process, whereby a top surface of the substrate 100 having a small crystal defect is used as a seed to perform a necessary structural transformation and a rapid growth. Accordingly, the light waveguide including the first semiconductor pattern 215 may have a small amount of transfer loss. Methods of forming a semiconductor material are not limited thereto.

The first semiconductor pattern 215, the second insulating interlayer 220, and the second isolation layer pattern 115 surrounding the first semiconductor pattern 215 may serve as other optical devices such as an optical coupler and a phase shifter, but are not limited thereto.

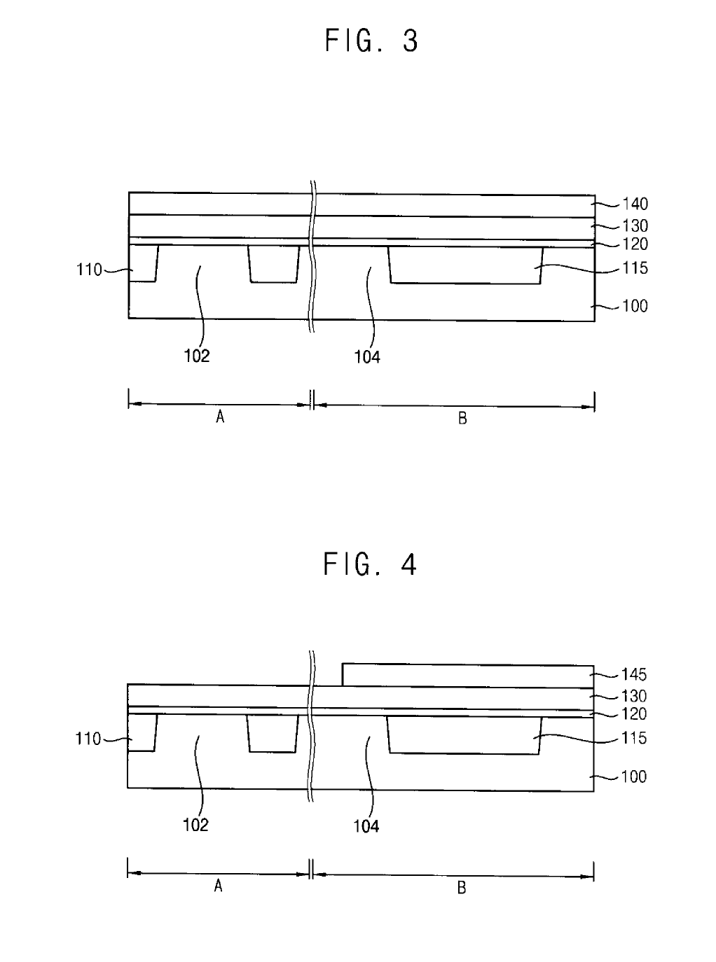

FIGS. 3 through 12 are cross-sectional views illustrating stages of manufacturing a semiconductor apparatus in accordance with example embodiments of the present general inventive concept. This method illustrated herein may be used in manufacturing the semiconductor apparatus of FIGS. 1 and 2, however, may not be limited thereto.

Referring to FIG. 3, an insulation layer 120, a first conductive layer 130, and a second etch stop layer 140 may be sequentially formed on the substrate 100 having a first isolation layer pattern 110 and a second isolation layer pattern 115 thereon.

The substrate 100 may include first and second regions A and B, respectively. The first region A may be an electronic device region, and the second region B may be an optical device region.

In an exemplary embodiment of the present general inventive concept, the first isolation layer pattern 110 and the second isolation layer pattern 115 may be formed by a shallow trench isolation (STI), but are not limited thereto. The first isolation layer pattern 110 may be formed on the substrate 100 in the first region A, and the second isolation layer pattern 115 may be formed on the substrate 100 in the second region B. The substrate 100 may be divided into active regions and field regions by the first isolation pattern 110 and the second isolation layer pattern 115. The active regions are the regions where neither of the first isolation layer pattern 110 nor the second isolation layer pattern115 is formed, and the field regions are the regions where at least one of the first isolation layer pattern 110 or the second isolation layer pattern 115 is formed. Particularly, a first active region 102 is located in the first region A, and a second active region 104 is located in the second region B.

The insulation layer 120 may be formed to include silicon oxide, but is not limited thereto. The insulation layer 120 may be formed by a thermal oxidation process on a top surface of the substrate 100. Alternatively, the insulation layer 120 may be formed by a chemical vapor deposition (CVD) process, an atomic layer deposition (ALD) process, or a physical vapor deposition (PVD) process. Methods of forming the insulation layer 120 are not limited thereto.

The first conductive layer 130 may be formed to include a material having a high etch selectivity with respect to the insulation layer 120 such as doped polysilicon, but is not limited thereto. The first conductive layer 130 may be formed to have a thickness greater than that of the insulation layer 120.

The second etch stop layer 140 may be formed to include a material having a high etch selectivity with respect to the first conductive layer 130. When the first conductive layer 130 includes doped polysilicon, the second etch stop layer 140 may be formed to include a material such as silicon oxide or silicon nitride, but is not limited thereto. When the second etch stop layer 140 includes silicon oxide, the second etch stop layer 140 may be formed to have a thickness equal to or greater than that of the insulation layer 120.

Referring to FIG. 4, the second etch stop layer 140 may be partially removed to form a second etch stop layer pattern 145 in the second region B, and a portion of the first conductive layer 130 in the first region A of the substrate 100 may be exposed.

The second etch stop layer pattern 145 may be formed to overlap the second isolation layer pattern 115 and a portion of the substrate 100 adjacent thereto in the second region B.

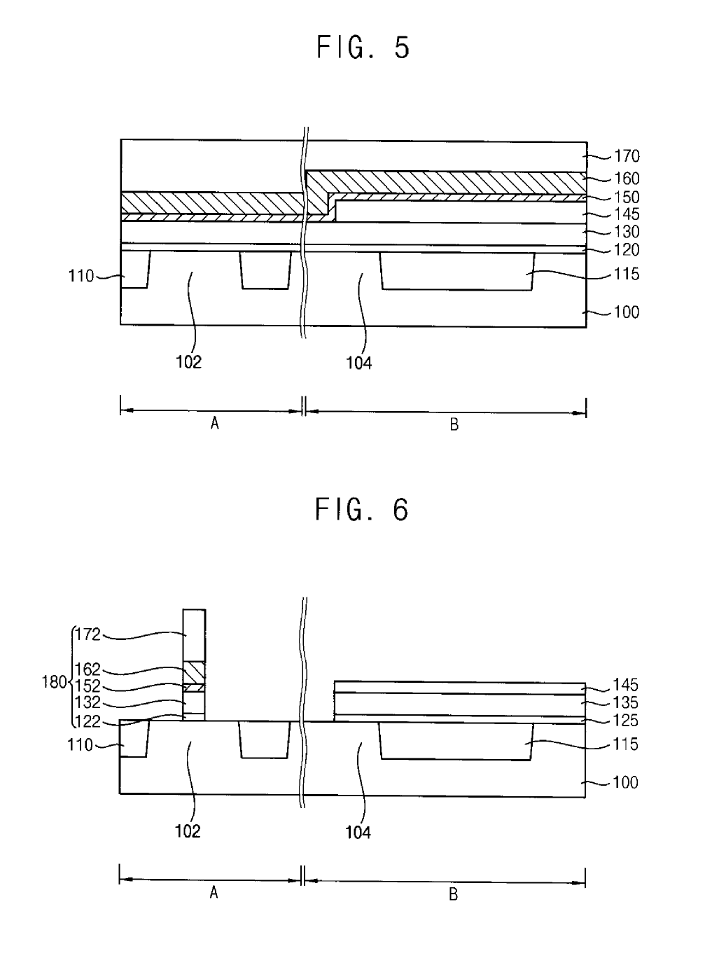

Referring to FIG. 5, a second conductive layer structure and a mask layer 170 may be sequentially formed on the exposed portion of the first conductive layer 130 and the second etch stop layer pattern 145.

The second conductive layer structure may be formed to include a barrier layer 150 and a metal layer 160 sequentially stacked on the second etch stop layer pattern 145.

The barrier layer 150 may include a metal nitride, such as titanium nitride, tantalum nitride, and tungsten nitride, but is not limited thereto. The metal layer 160 may be formed to include a metal such as tungsten, titanium, tantalum, or copper, but is not limited thereto. The mask layer 170 may be formed to include silicon nitride, but is not limited thereto. In some cases, the barrier layer 150 may not be formed.

Referring to FIG. 6, the mask layer 170 may be patterned to form a mask 172 in the first region A. The metal layer 160, the barrier layer 150, the first conductive layer 130, and the insulation layer 120 may be patterned using the mask 172 as an etching mask to form a first gate structure 180 on the substrate 100 in the first region A. The first gate structure 180 may include a gate insulation layer pattern 122, a gate conductive layer pattern 132, a barrier layer pattern 152, a gate metal layer pattern 162 and a mask 172 sequentially stacked on the substrate 100 in the first region A. The gate conductive layer pattern 132, the barrier layer pattern 152, and the gate metal layer pattern 162 may define a first gate electrode.

During the etching process, portions of the metal layer 160 and the barrier layer 150 in the second region B may be removed, however, portions of the first conductive layer 130 and the insulation layer 120 in the second region B covered by the second etch stop layer pattern 145 may not be removed. Hereinafter, the portions of the first conductive layer 130 and the insulation layer 120 remaining in the second region B may be referred to as a first etch stop layer pattern 135 and an insulation layer pattern 125, respectively.

During the etching process to pattern the first conductive layer 130, the second etch stop layer pattern 145 may remain due to its high etch selectivity compared to that of the first conductive layer 130. The first etch stop layer pattern 135 and the insulation layer pattern 125 under the second etch stop layer pattern 145 may also remain.

The second etch stop layer pattern 145 may be etched together with the insulation layer 120 in the first region A, when they both include silicon oxide. The second etch stop layer pattern 145 may not be completely removed but remain when the second etch stop layer 140 has a thickness greater than that of the insulation layer 120. When the second etch stop layer 140 has a thickness substantially the same as that of the insulation layer 120, the second etch stop layer 140 may be completely removed, however, at least the first conductive layer 130 may not be removed but remain.

Hereinafter, the insulation layer pattern 125, the first etch stop layer pattern 135, and the second etch stop layer pattern 145 sequentially stacked on the substrate 100 in the second region B may be referred to as a first etch stop layer structure 111.

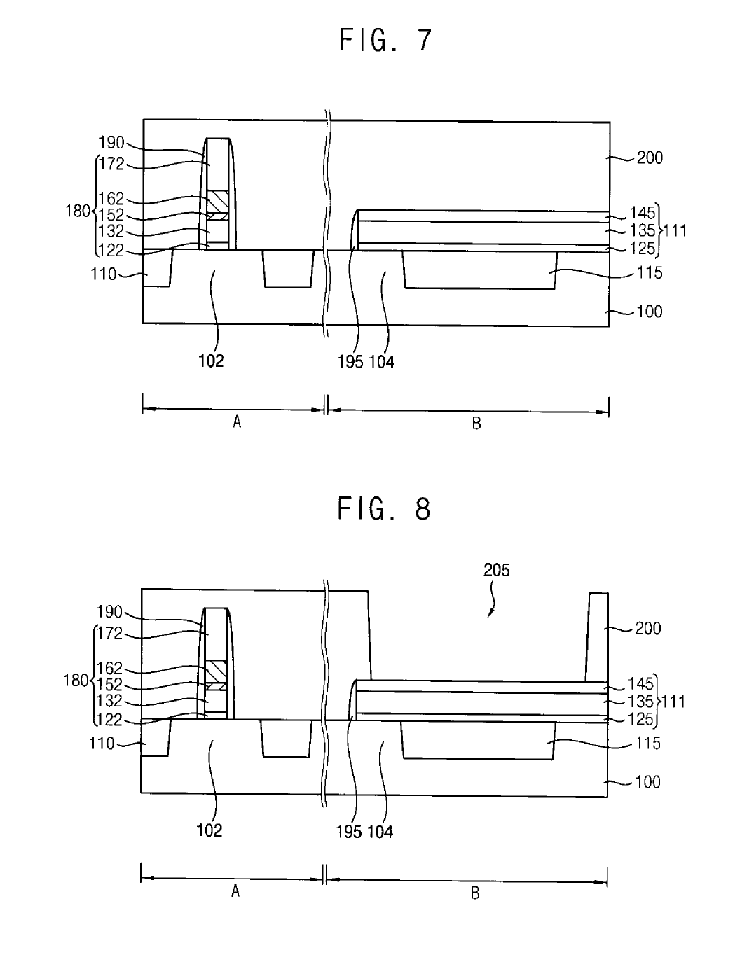

Referring to FIG. 7, a spacer layer covering the first gate structure 180 and the first etch stop layer structure 111 may be formed on the substrate 100, and the spacer layer may be anisotropically etched to form a first spacer 190 on a sidewall of the first gate structure 180 and a second spacer 195 on a sidewall of the first etch stop layer structure 111. The spacer layer may be formed to include silicon nitride, but is not limited thereto.

After forming a photoresist pattern (not illustrated) covering the second region B, an ion implantation process may be performed using the photoresist pattern, the first gate structure 180, and the first spacer 190 as an ion implantation mask to form an impurity region (not illustrated) at an upper portion of the first active region 102 of the substrate 100 adjacent to the first gate structure 180. A heat treatment process may be further performed.

After removing the photoresist pattern, a first insulating interlayer 200 may be formed on the substrate 100 to cover the first gate structure 180, the first etch stop layer structure 111, the first spacer 190, and the second spacer 195. The first insulating interlayer 200 may be formed to include silicon oxide, but is not limited thereto.

In an exemplary embodiment of the present general inventive concept, a planarization process on an upper portion of the first insulating interlayer 200 may be further performed. The planarization process may include a chemical mechanical polishing (CMP) process and/or an etch back process, but is not limited thereto.

Referring to FIG. 8, the first insulating interlayer 200 may be partially removed to form a first opening 205 to expose the first etch stop layer structure 111.

Particularly, a portion of the first insulating interlayer 200 on the first etch stop layer structure 111 may be removed to form the first opening 205 exposing a top surface of the second etch stop layer pattern 145. In preparation for a mis-alignment, the first opening 205 may not completely expose the top surface of the second etch stop layer pattern 145, and an edge of the top surface of the second etch stop layer pattern 145 may be covered by the first insulating interlayer 200.

The first insulating interlayer 200 may be etched by a dry etching process. In some cases, when the second etch stop layer pattern 145 includes silicon oxide as does the first insulating interlayer 200, the second etch stop layer pattern 145 may also be etched in the dry etching process to form the first opening 205. The first etch stop layer pattern 135 may include a material having a high etch selectivity with respect to the first insulating interlayer 200, thereby not being etched during the etching process.

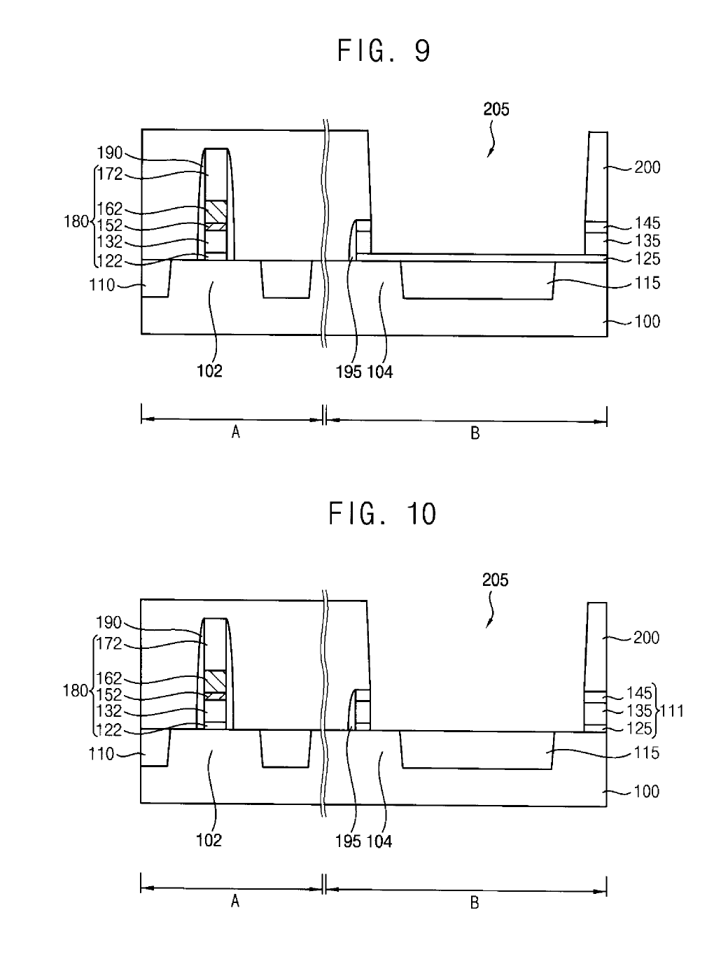

Referring to FIG. 9, the second etch stop layer pattern 145 exposed by the first opening 205 and the first etch stop layer pattern 135 therebeneath may be removed to expose the insulation layer pattern 125. Thus, the first opening 205 may be expanded vertically, i.e., toward a direction substantially perpendicular to a top surface of the substrate 100.

That is, when the second etch stop layer pattern 145 is not etched during the formation of the first opening 205, after etching the second etch stop layer pattern 145, the first etch stop layer pattern 135 may be etched. Alternatively, when the second etch stop layer pattern 145 is etched during the formation of the first opening 205, only the first etch stop layer pattern 135 may be etched.

In an exemplary embodiment of the present general inventive concept, the first etch stop layer pattern 135 may be etched by a dry etching process. The first etch stop layer pattern 135 may have a high etch selectivity with respect to the insulation layer pattern 125 thereunder, and thus the insulation layer pattern 125 may serve as an etching end point.

Referring to FIG. 10, the insulation layer pattern 125 exposed by the first opening 205 may be removed to expose top surfaces of the substrate 100 and the second isolation layer pattern 115. Thus, the first opening 205 may be expanded vertically, i.e., toward a direction substantially perpendicular to the top surface of the substrate 100.

The insulation layer pattern 125 may be removed by a wet etching process. The insulation layer pattern 125 may be formed to have a thickness smaller than that of the first etch stop layer pattern 135, and thus the substrate 100 may be less damaged during the etching process.

The second isolation layer pattern 115 and a top surface of the substrate 100 adjacent thereto may be exposed by the first opening 205.

An edge portion of the first etch stop layer structure 111 may remain after the etching process.

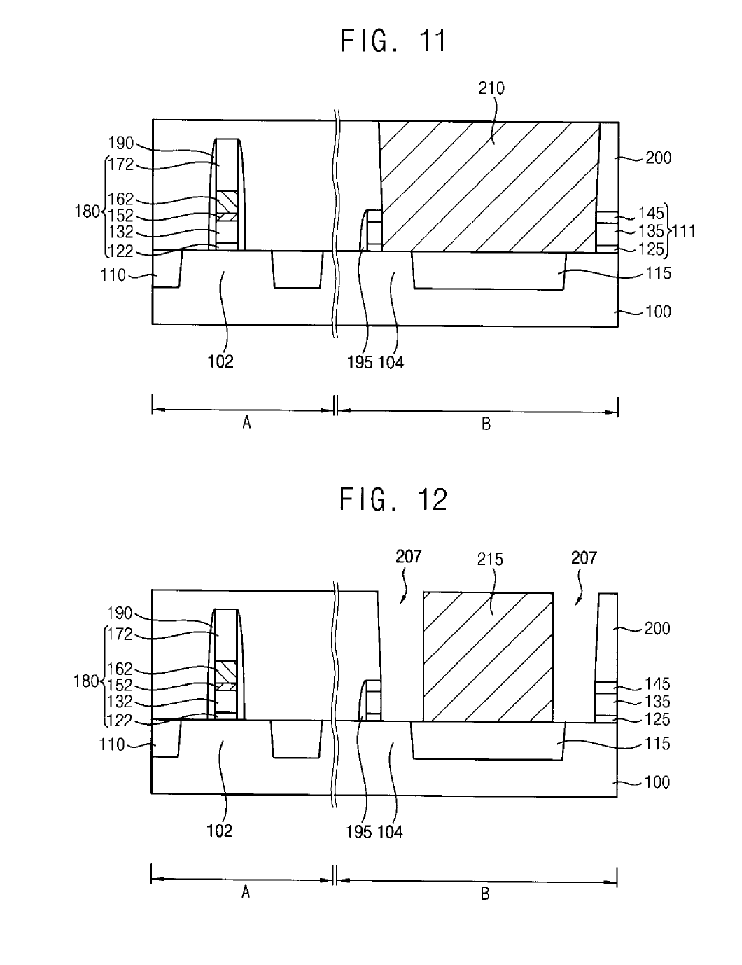

Referring to FIG. 11, a semiconductor layer 210 may be formed to fill the first opening 205.

Particularly, an amorphous semiconductor layer may be formed on the substrate 100, the second isolation layer pattern 115 and the first insulating interlayer 200 to sufficiently fill the first opening 205, and the amorphous semiconductor layer may be crystallized using the top surface of the substrate 100 exposed by the first opening 205 as a seed to form the semiconductor layer 210 including a single crystalline semiconductor material. An upper portion of the semiconductor layer 210 may be planarized until a top surface of the first insulating interlayer 200 is exposed.

The amorphous semiconductor layer may be formed to include silicon or germanium, but is not limited thereto. The amorphous semiconductor layer may be formed by a CVD process, an ALD process, or a PVD process using silicon, but is not limited thereto.

The single crystalline semiconductor layer 210 may be formed by heating the amorphous semiconductor layer or emitting a laser on the amorphous semiconductor layer. In example embodiments of the present general inventive concept, the crystallization process may be performed by a solid phase epitaxy (SPE) process, or a laser epitaxial growth (LEG) process.

As illustrated above, the top surface of the substrate 100 exposed by the first opening 205 may be less damaged when the first etch stop layer structure 111 is etched, and thus the top surface of the substrate 100 serving as the seed may have less crystal defect. Accordingly, the single crystalline semiconductor layer 210 may have good crystalline characteristics.

Referring to FIG. 12, the semiconductor layer 210 may be patterned to form a first semiconductor pattern 215.

The first semiconductor pattern 215 may serve as an optical device, such as a core of a light waveguide. The core may include a single crystalline semiconductor material having good crystalline characteristics, thereby only causing a small amount of signal transfer loss.

As the semiconductor layer 210 is patterned, a second opening 207 may be formed adjacent to the first semiconductor pattern 215, thereby exposing an edge of the top surface of the isolation layer pattern 115 and a top surface of the substrate 100 adjacent thereto.

Referring to FIG. 2, a second insulating interlayer 220 may be formed on the substrate 100, the second isolation layer pattern 115, and the first insulating interlayer 200 to sufficiently cover the first semiconductor pattern 215 to complete the semiconductor apparatus.

The second insulating interlayer 220 may be formed to include silicon oxide, and may be merged with the first insulating interlayer 200 that may also include silicon oxide. A planarization process may be further performed on an upper portion of the second insulating interlayer 220. The planarization process may be performed by a CMP process and/or an etch back process.

When the first semiconductor pattern 215 serves as a core, the second isolation layer pattern 115 and the second insulating interlayer 220 surrounding the first semiconductor pattern 215 may serve as a cladding, and thus the first semiconductor pattern 215, the second isolation layer pattern 115 and the second insulating interlayer 220 may serve as a light waveguide.

As described above, after forming an electronic device including the first gate structure 180 having a relatively large size, an optical device including the first semiconductor pattern 215 having a relatively small size may be formed, so that the optical device may be prevented from being damaged by a planarization process on the first insulating interlayer 200 covering the electronic device.

Additionally, a heat treatment process may be used in forming the electronic device before the optical device is formed on the same substrate 100, so that the physical characteristics of silicon supporting the optical device are not damaged.

Furthermore, the first etch stop layer pattern 135 formed between the substrate 110 and the first insulating interlayer 200 may have a high etch selectivity with respect to the first insulating interlayer 200, so that the single crystalline semiconductor material included in the substrate 100 may be protected from the etching damage during the etching process directed to the first insulating interlayer 200. Thus, the optical device formed using the single crystalline semiconductor material as a seed may have good characteristics.

FIG. 13 is a cross-sectional view illustrating a semiconductor apparatus in accordance with an exemplary embodiment of the present general inventive concept. The semiconductor apparatus may be substantially the same as or similar to that illustrated with reference to FIGS. 1 and 2 except for the gate electrode. Thus, like reference numerals refer to like elements, and detailed explanations thereon are omitted herein.

Referring to FIG. 13, the semiconductor apparatus may include a second gate structure 185, a first semiconductor pattern 215, and a first etch stop layer structure 111 on a substrate 100. The semiconductor apparatus may further include first and second insulating interlayers 200 and 220.

The second gate structure 185 may include a gate insulation layer pattern 122, a second gate electrode and a mask 172 sequentially stacked on the substrate 100 in the first region A. The second gate electrode may include a gate conductive layer pattern 132. Unlike the first gate electrode illustrated in FIGS. 1 and 2, the second gate electrode may include only the gate conductive layer pattern 132, without a barrier layer pattern 152 or a gate metal layer pattern 162. The gate conductive layer pattern 132 may include doped polysilicon, but is not limited thereto.

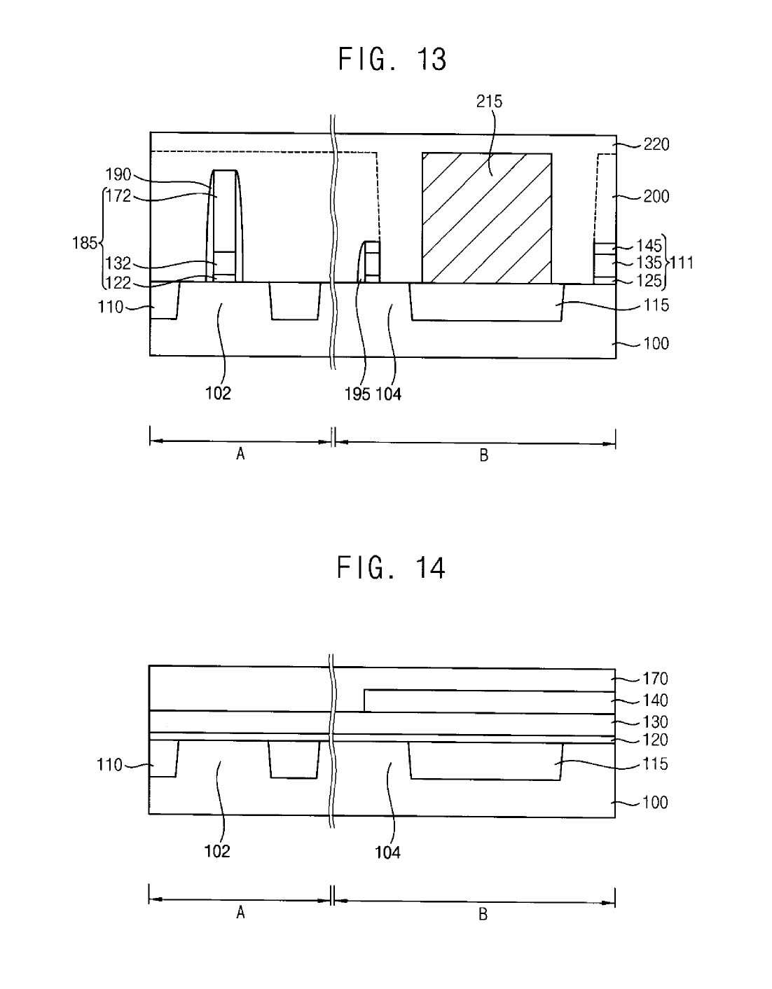

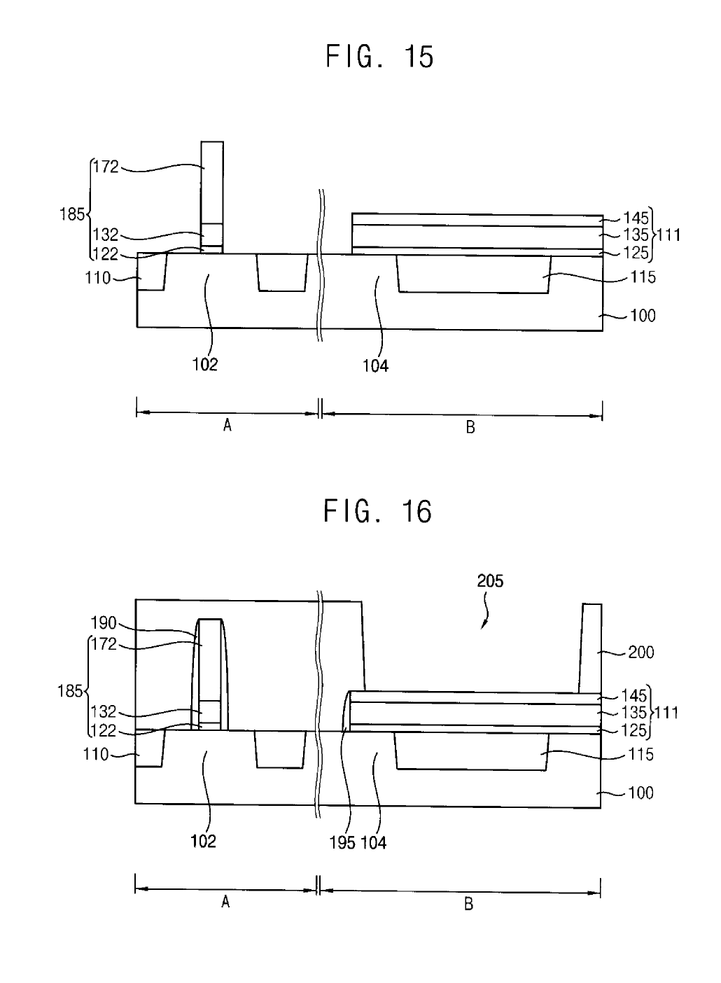

FIGS. 14 through 16 are cross-sectional views illustrating stages of a method of manufacturing a semiconductor apparatus in accordance with an exemplary embodiment of the present general inventive concept. This method may be used in manufacturing the semiconductor apparatus of FIG. 13, however, may not be limited thereto. Additionally, this method may include processes substantially the same as or similar to those illustrated with reference to FIGS. 3 through 12. Thus, like reference numerals refer to like elements, and detailed explanations thereon are omitted herein.

Referring to FIG. 14, processes substantially the same as or similar to those illustrated with reference to FIGS. 3 through 4 may be performed. Thus, an insulation layer 120, a first conductive layer 130, and a second etch stop layer 140 may be sequentially formed on a substrate 100 having first and second isolation layer patterns 110 and 115 thereon, respectively, and the second etch stop layer 140 may be patterned to form a second etch stop layer pattern 145 in the second region B of the substrate 100. A mask layer 170 may be formed on the first conductive layer 130 and the second etch stop layer pattern 145.

Referring to FIG. 15, a process substantially the same as or similar to those illustrated with reference to FIG. 6 may be performed.

Thus, the mask layer 170 may be patterned to form a mask 172 in the first region A, and the first conductive layer 130 and the insulation layer 120 may be patterned using the mask 172 as an etching mask to form a second gate structure 185 on the substrate 100 in the first region A. The second gate structure 185 may include a gate insulation layer pattern 122, a gate conductive layer pattern 132 and a mask 172 sequentially stacked on the substrate 100 in the first region A. The gate conductive layer pattern 132 may define a second gate electrode. Additionally, in the second region B, a first etch stop layer structure 111 including an insulation layer pattern 125, a first etch stop layer pattern 135, and a second etch stop layer pattern 145 sequentially stacked on the substrate 100 may be formed.

Referring to FIG. 16, processes substantially the same as or similar to those illustrated with reference to FIGS. 7 through 8 may be performed.

Thus, a first spacer 190 and a second spacer 195 may be formed on sidewalls of the second gate structure 185 and the first etch stop layer structure 111, respectively, and a first insulating interlayer 200 covering the second gate structure 185, the first etch stop layer structure 111, the first spacer 190, and the second spacer 195 may be formed on the substrate 100. The first insulating interlayer 200 may be partially removed to form a first opening 205 exposing the first etch stop layer structure 111.

Referring to FIG. 13, processes substantially the same as or similar to those illustrated with reference to FIGS. 9 through 12 and FIG. 2 may be performed to manufacture the semiconductor apparatus.

A top surface of the substrate 100 exposed by the first opening 205 may not be damaged when the first etch stop layer structure 111 is etched. Thus, the top surface of the substrate 100 may have less crystal defect, so that a first semiconductor pattern 215 formed using the top surface of the substrate 100 as a seed may have good crystalline characteristics.

FIG. 17 is a cross-sectional view illustrating a semiconductor apparatus in accordance with an exemplary embodiment of the present general inventive concept. The semiconductor apparatus may be substantially the same as or similar to that illustrated with reference to FIGS. 1 and 2 except for the first etch stop layer structure 111. Thus, like reference numerals refer to like elements, and detailed explanations thereon are omitted herein.

Referring to FIG. 17, the semiconductor apparatus may include a first gate structure 180, a first semiconductor pattern 215 and a second etch stop layer structure 121 on a substrate 100. The semiconductor apparatus may further include a first insulating interlayer 200 and a second insulating interlayer 220.

The second etch stop layer structure 121 may include an insulation layer pattern 125, a third etch stop layer pattern 235 and a second etch stop layer pattern 145 sequentially stacked on the substrate 100 in the second region B. The second etch stop layer structure 121 may not include the second etch stop layer pattern 145. The second etch stop layer structure 121 may be formed on a top surface of the substrate 100 adjacent to the second isolation layer pattern 115 on which the first semiconductor pattern 215 is formed, and may be spaced apart from the first semiconductor pattern 215.

The insulation layer pattern 125 may include a material substantially the same as that of the gate insulation layer pattern 122. The insulation layer pattern 125 may include silicon oxide, but is not limited thereto.

The third etch stop layer pattern 235 may include a material having a high etch selectivity with respect to the first insulating interlayer 200 and the insulation layer pattern 125, such as silicon nitride, but is not limited thereto.

The second etch stop layer pattern 145 may include a material having a high etch selectivity with respect to the third etch stop layer pattern 235, such as silicon oxide, but is not limited thereto.

A second spacer 195 may be further formed on a sidewall of the second etch stop layer structure 121.

The first semiconductor pattern 215 may include a single crystalline semiconductor material that may be formed using a top surface of the substrate 100 having less crystal defect as a seed, leading to good crystalline characteristics of the first semiconductor pattern 215. Accordingly, the light waveguide including the first semiconductor pattern 215 may have a small amount of signal transfer loss.

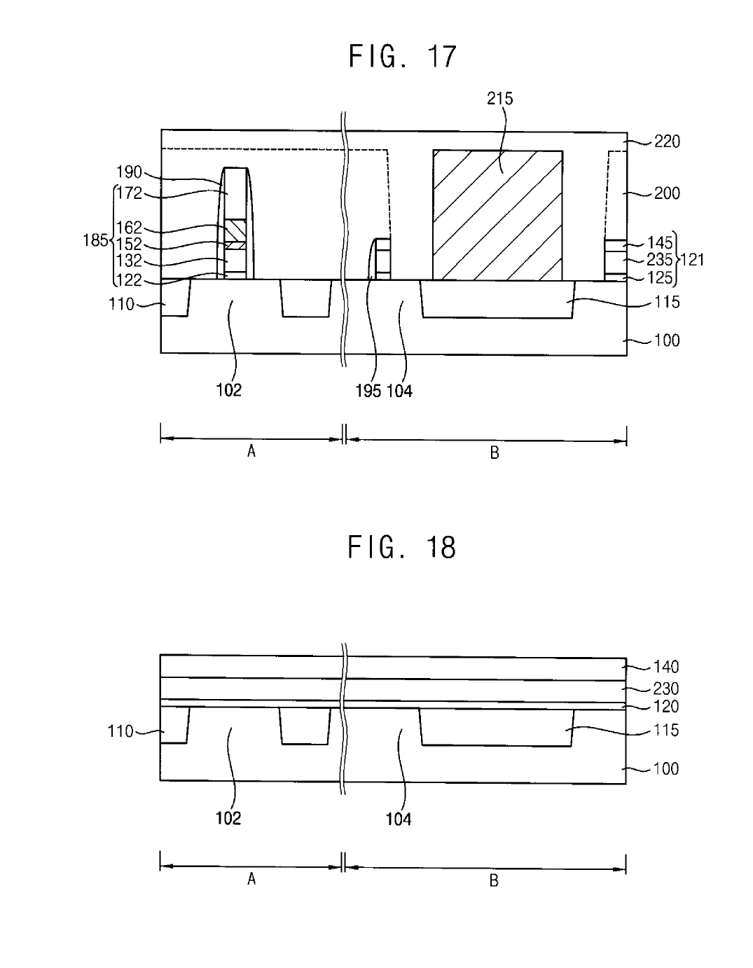

FIGS. 18 through 23 are cross-sectional views illustrating stages of a method of manufacturing a semiconductor apparatus in accordance with an exemplary embodiment of the present general inventive concept. This method may be used in manufacturing the semiconductor apparatus illustrated in FIG. 17, however, may not be limited thereto. Additionally, this method may include processes substantially the same as or similar to those illustrated with reference to FIGS. 3 through 12. Thus, like reference numerals refer to like elements, and detailed explanations thereon are omitted herein.

Referring to FIG. 18, a process substantially the same as or similar to that illustrated with reference to FIG. 3 may be performed. However, a third etch stop layer 230 may be formed instead of the first conductive layer 130.

That is, an insulation layer 120, the third etch stop layer 230, and a second etch stop layer 140 may be sequentially formed on a substrate 100 having the first isolation layer pattern 110 and the second isolation layer pattern 115 thereon.

The insulation layer 120 may be formed to include silicon oxide, but is not limited thereto. The third etch stop layer 230 may be formed to include a material having a high etch selectivity with respect to the insulation layer 120 and a first insulating interlayer 200 (refer to FIG. 22) such as silicon nitride, but is not limited thereto. The second etch stop layer 140 may be formed to include a material having a high etch selectivity with respect to a first conductive layer 130 (refer to FIG. 20) such as silicon oxide, but is not limited thereto.

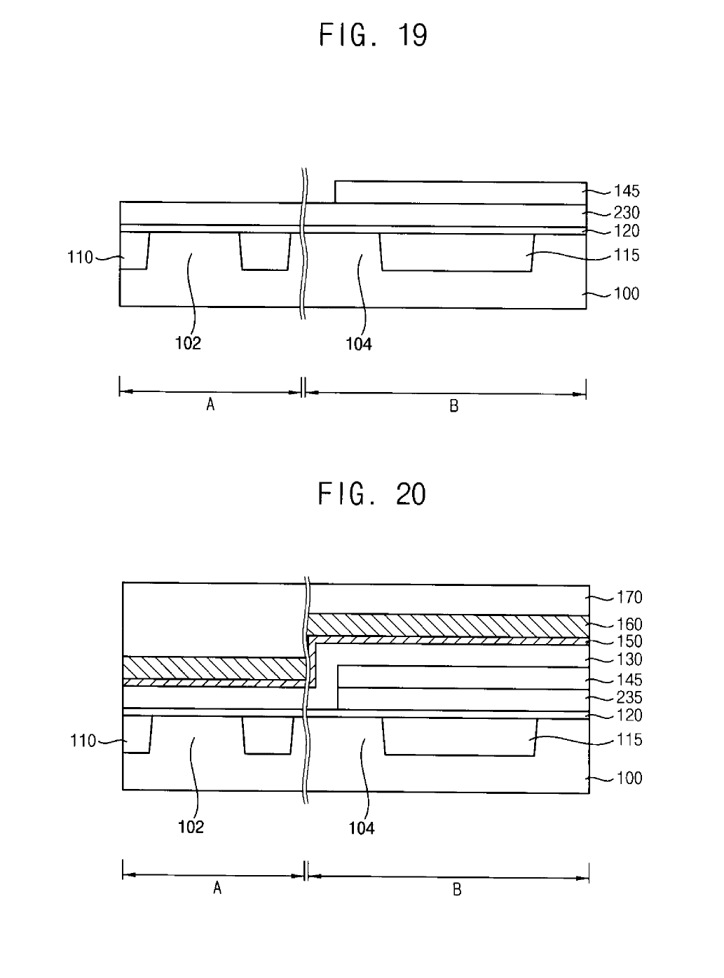

Referring to FIG. 19, a process substantially the same as or similar to those illustrated with reference to FIG. 4 may be performed. Thus, the second etch stop layer 140 may be partially removed to form a second etch stop layer pattern 145 in the second region B of the substrate 100.

Referring to FIG. 20, the third etch stop layer 230 may be etched using the second etch stop layer pattern 145 as an etching mask to form a third etch stop layer pattern 235.

A process substantially the same as or similar to that illustrated with reference to FIG. 5 may be performed to sequentially form a second conductive layer structure and a mask layer 170 on the insulation layer 120, the third etch stop layer pattern 235 and the second etch stop layer pattern 145.

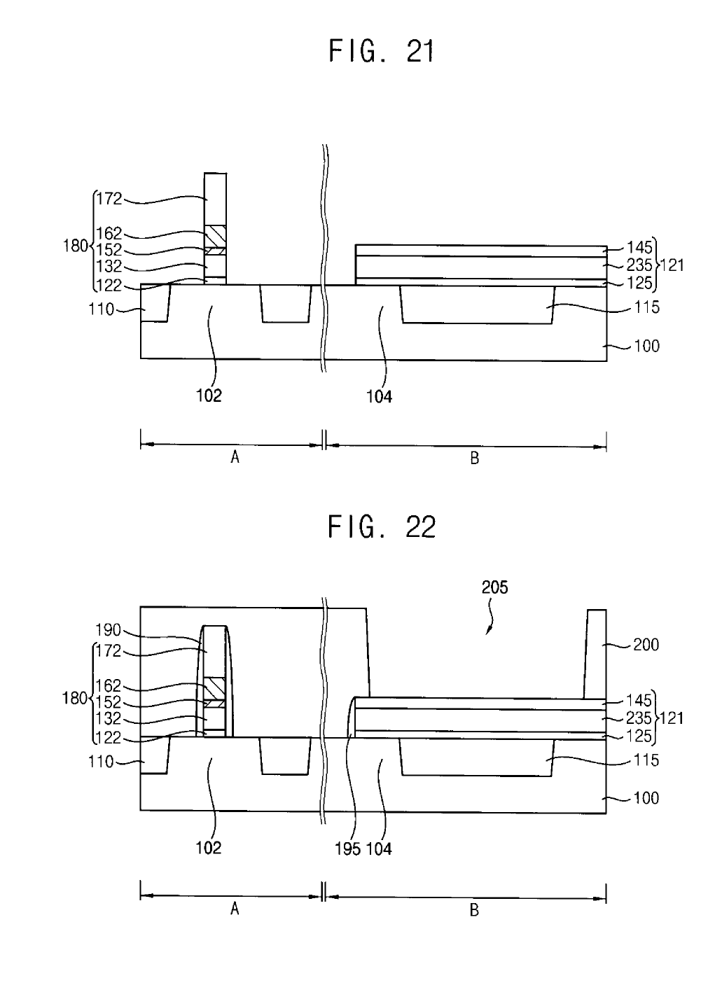

Referring to FIG. 21, a process substantially the same as or similar to that illustrated with reference to FIG. 6 may be performed.

Thus, a first gate structure 180 including a gate insulation layer pattern 122, a gate conductive layer pattern 132, a barrier layer pattern 152, a gate metal layer pattern 162, and a mask 172 sequentially stacked on the substrate 100 may be formed in the first region A. Additionally, a second etch stop layer structure 121 including an insulation layer pattern 125, the third etch stop layer pattern 235 and the second etch stop layer pattern 145 sequentially stacked on the substrate 100 may be formed in the second region B of the substrate 100.

Referring to FIG. 22, processes substantially the same as or similar to those illustrated with reference to FIGS. 7 to 8 may be performed.

Thus, the first spacer 190 and the second spacer 195 may be formed on sidewalls of the first gate structure 180 and the second etch stop layer structure 121, respectively, and the first insulating interlayer 200 covering the first gate structure 180, the second etch stop layer structure 121, the first spacer 190, and the second spacer 195 may be formed on the substrate 100. The first insulating interlayer 200 may be partially removed to form a first opening 205 exposing the second etch stop layer structure 121.

Referring to FIG. 23, processes substantially the same as or similar to those illustrated with reference to FIGS. 9 through 10 may be performed.

Thus, the second etch stop layer pattern 145 exposed by the first opening 205, and the third etch stop layer pattern 235 and the insulation layer pattern 125 therebeneath may be removed to expose top surfaces of the substrate 100 and the second isolation layer pattern 115. Thus, the first opening 205 may be expanded vertically. The third etch stop layer pattern 235 may have a high etch selectivity with respect to the first insulating interlayer 200 and the insulation layer pattern 125, and thus the top surface of the substrate 100 exposed by the first opening 205 may not be damaged. Accordingly, the top surface of the substrate 100 may have less crystal defect.

Referring to FIG. 17, processes substantially the same as or similar to those illustrated with reference to FIGS. 11 through 12 and FIG. 2 may be performed to complete the semiconductor apparatus.

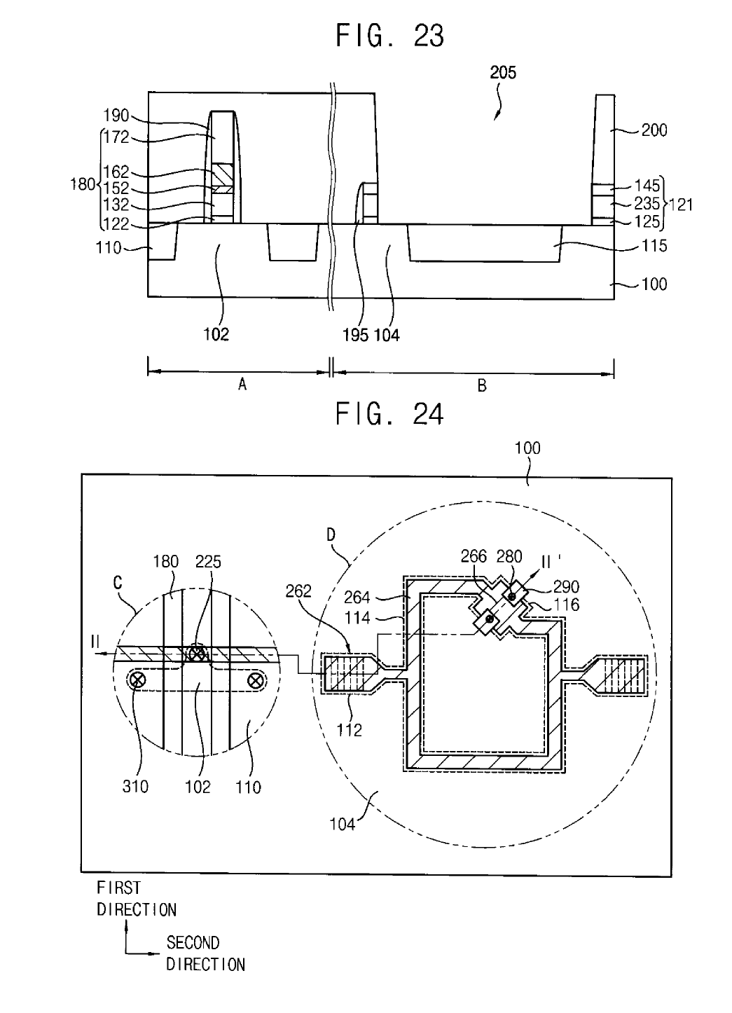

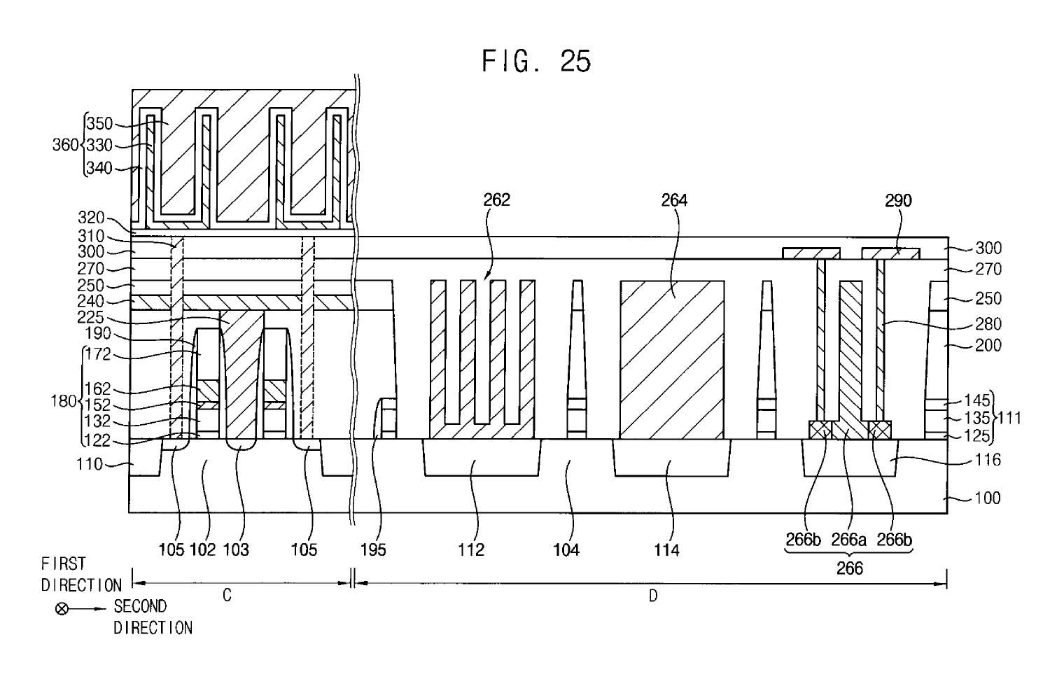

FIG. 24 is a plan view illustrating a semiconductor apparatus in accordance with an exemplary embodiment of the present general inventive concept, and FIG. 25 is a cross-sectional view of the semiconductor apparatus cut along the line II-II′ of FIG. 24. For the convenience of explanation, only some of the elements, such as a first gate structure, active regions, second to fourth semiconductor patterns, are illustrated in FIG. 24. The semiconductor apparatus may be substantially the same as or similar to that illustrated with reference to FIGS. 1 and 2, except that a bit line 240 and a capacitor 360 may be further included and the second through fourth semiconductor patterns instead of the first semiconductor pattern may be formed. Thus, like reference numerals refer to like elements, and detailed explanations thereon are omitted herein.

Referring to FIGS. 24 and 25, the semiconductor apparatus may include a first gate structure 180, a bit line 240, a capacitor 360, semiconductor patterns 262, 264, and 266, respectively, and a first etch stop layer structure 111. The semiconductor apparatus may further include first and third through fifth insulating interlayers 200, 250, 270, and 300, respectively.

The substrate 100 may include third and fourth regions C and D, respectively. In an exemplary embodiment of the present general inventive concept, the third region C may be an electronic device region, and the fourth region D may be an optical device region.

First and third through fifth isolation layer patterns 110, 112, 114, and 116, respectively, may be formed on the substrate 100. The first isolation layer pattern 110 may be formed on the substrate 100 in the third region C, and the third through fifth isolation layer patterns 112, 114, and 116, respectively, may be formed on the substrate 100 in the fourth region D. The substrate 100 may contain active regions defined by a lack of coverage by one of the isolation layer patterns 110, 112, 114, and 116, respectively. Particularly, a region of the substrate 100 on which the first isolation layer pattern 110 is not formed in the third region C may be defined as a first active region 102, and a region of the substrate 100 on which any one of the third through fifth isolation layer patterns 112, 114, and 116, respectively is not formed in the fourth region D may be defined as a second active region 104. The first and third through fifth isolation layer patterns 110, 112, 114, and 116, respectively, may include an insulating material such as silicon oxide, but is not limited thereto.

In example embodiments of the present general inventive concept, a plurality of first gate structures 180 may be formed on the substrate 100 in the third region C. Each first gate structure 180 may extend in a first direction substantially parallel to a top surface of the substrate 100, and the plurality of first gate structures 180 may be spaced apart from each other in a second direction substantially parallel to the top surface of the substrate 100 and substantially perpendicular to the first direction. A first impurity region 103 may be formed at an upper portion of the substrate 100 between the first gate structures 180, and a second impurity region 105 may be formed at upper portions of the substrate 100 between each first gate structure 180 and the first isolation layer pattern 110.

The first gate structures 180 may be covered by the first insulating interlayer 200, and a first contact plug 225 may be formed through the first insulating interlayer 200 between the first gate structures 180. The first contact plug 225 may contact the first impurity region 103. The first insulating interlayer 200 may cover a top surface of the first etch stop layer structure 111.

The bit line 240 may be formed on the first insulating interlayer 200 to contact a top surface of the first contact plug 225. The bit line 240 may extend in the second direction. The bit line 240 may be covered by the third insulating interlayer 250.

The second through fourth semiconductor patterns 262, 264, and 266, respectively, may be formed on the third through fifth isolation layer patterns 112, 114, and 116, respectively, in the fourth region D. The second through fourth semiconductor patterns 262, 264, and 266, respectively, may be formed in a center position on top of the isolation layer patterns 112, 114 and 116, respectively, without covering edges of a corresponding isolation layer pattern.

The second through fourth semiconductor patterns 262, 264, and 266, respectively, may include single crystalline silicon or single crystalline germanium, but are not limited thereto. Top surfaces and sidewalls of the second to fourth semiconductor patterns 262, 264, and 266, respectively, may be covered by the fourth insulating interlayer 270. The fourth semiconductor pattern 266 may include a protruding central portion 266a and flat edge portions 266b when viewed from a top side. Impurities may be doped into the edge portions 266b of the fourth semiconductor pattern 266.

The second semiconductor pattern 262, the fourth insulating interlayer 270, and the third isolation layer pattern 112 surrounding the second semiconductor pattern 262 may serve as an optical coupler. The third semiconductor pattern 262, the fourth insulating interlayer 270, and the fourth isolation layer pattern 114 surrounding the third semiconductor pattern 262 may serve as a light waveguide. The fourth semiconductor pattern 266, the fourth insulating interlayer 270, and the fifth isolation layer pattern 116 surrounding the fourth semiconductor pattern 266, a third contact plug 280, and electrodes 290 may serve as a phase shifter. That is, the second through fourth semiconductor patterns 262, 264, and 266, respectively, may serve as cores of the optical devices, and the fourth insulating interlayer 270, the isolation layer patterns 112, 114, and 116, respectively, surrounding the second through fourth semiconductor patterns 262, 264, and 266, respectively, may serve as claddings of the optical devices.

The edge portions 266b of the fourth semiconductor pattern 266 serving as the core of the phase shifter may be electrically connected to the electrodes 290 via the third contact plug 280, which may be formed through the fourth insulating interlayer 270. The electrodes 290 may be formed on the fourth insulating interlayer 270, and may be covered by the fifth insulating interlayer 300.

The first etch stop layer structure 111 may be formed on top surfaces of the substrate 100 adjacent to the third through fifth isolation layer patterns 112, 114, and 116, respectively, on which the second through fourth semiconductor patterns 262, 264, and 266 are formed, respectively, and may be spaced apart from the second through fourth semiconductor patterns 262, 264, and 266, respectively.

The capacitor 360 may be formed on the fifth insulating interlayer 300, and a fourth etch stop layer pattern 320 may be formed between the capacitor 360 and the fifth insulating interlayer 300. The capacitor 360 may be electrically connected to the second impurity region 105 via a second contact plug 310, which may be formed through the first and third through fifth insulating interlayers 200, 250, 270, and 300, respectively. The capacitor 360 may include a lower electrode 330, a dielectric layer 340 and an upper electrode 350 sequentially stacked, and may be covered by a sixth insulating interlayer (not illustrated).

The first and third through fifth insulating interlayers 200, 250, 270, and 300, respectively, may include an insulating material such as silicon oxide and silicon nitride, but is not limited thereto. Some or all of the first and third through fifth insulating interlayers 200, 250, 270, and 300, respectively, may include substantially the same material, thereby may be merged into one layer. Particularly, the fourth insulating interlayer 270 may include a material substantially the same as that of the third to fifth isolation layer patterns 112, 114, and 116, respectively.

The semiconductor apparatus may include a second gate structure 185 instead of the first gate structure 180, or a second etch stop layer structure 121 instead of the first etch stop layer structure 111, like the semiconductor apparatus illustrated with reference to FIG. 13 or FIG. 17.

The second through fourth semiconductor patterns 262, 264, and 266, respectively, may include a semiconductor material formed by an epitaxial growth process using a top surface of the substrate 100 having less crystal defect as a seed, thereby having good crystalline characteristics. Accordingly, the optical devices including the second through fourth semiconductor patterns 262, 264, and 266, respectively, may have good characteristics.

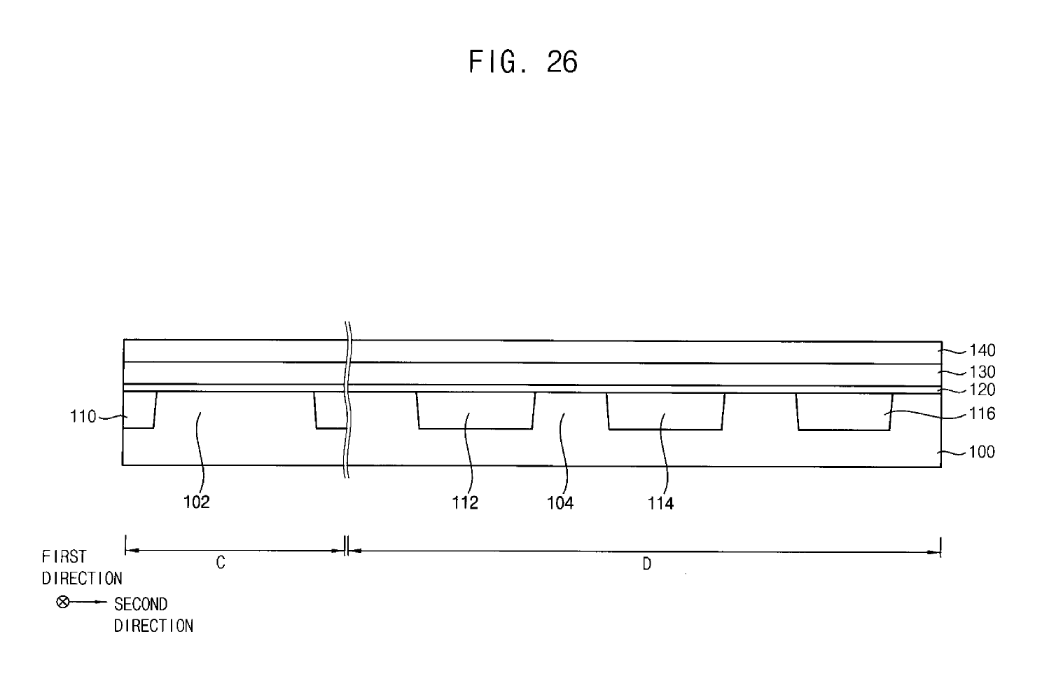

FIGS. 26 through 32 are cross-sectional views illustrating stages of a method of manufacturing a semiconductor apparatus in accordance with an exemplary embodiment of the present general inventive concept. This method may be used in manufacturing the semiconductor apparatus of FIGS. 24 and 25, however, may not be limited thereto. Additionally, this method may include processes substantially the same as or similar to those illustrated with reference to FIGS. 3 through 12. Thus, like reference numerals refer to like elements, and detailed explanations thereon are omitted herein.

Referring to FIG. 26, a process substantially the same as or similar to that illustrated with reference to FIG. 3 may be performed. However, a plurality of isolation layer patterns 112, 114, and 116 may be formed in the fourth region D.

That is, an insulation layer 120, a first conductive layer 130, and a second etch stop layer 140 may be sequentially formed on a substrate 100 including third and fourth regions C and D. Electronic devices and the first isolation layer pattern 112 may be formed in the third region C, and optical devices and the third through fifth isolation layer patterns 112, 114 and 116, respectively, may be formed in the fourth region D.

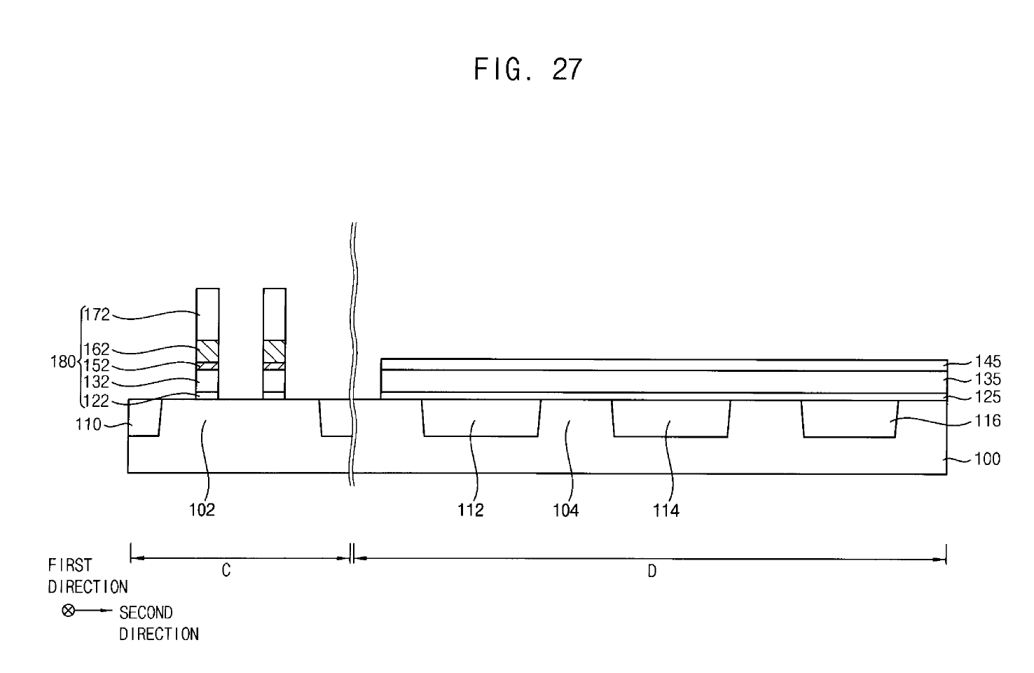

Referring to FIG. 27, processes substantially the same as or similar to those illustrated with reference to FIGS. 4 through 6 may be performed. However, a plurality of first gate structures 180 may be formed in the third region C.

Thus, the plurality of first gate structures 180, each of which may extend in a first direction substantially parallel to a top surface of the substrate 100, may be formed in a second direction substantially parallel to the top surface of the substrate 100 and substantially perpendicular to the first direction on the substrate 100 in the third region C. A first etch stop layer structure 111 may be formed on the substrate 100 in the fourth region D.

Each of the first gate structures 180 may include a gate insulation layer pattern 122, a gate conductive layer pattern 132, a barrier layer pattern 152, a gate metal layer pattern 162, and a mask 172 sequentially stacked on the substrate 100, and the first etch stop layer structure 111 may include an insulation layer pattern 125, a first etch stop layer pattern 135 and a second etch stop layer pattern 145 sequentially stacked on the substrate 100.

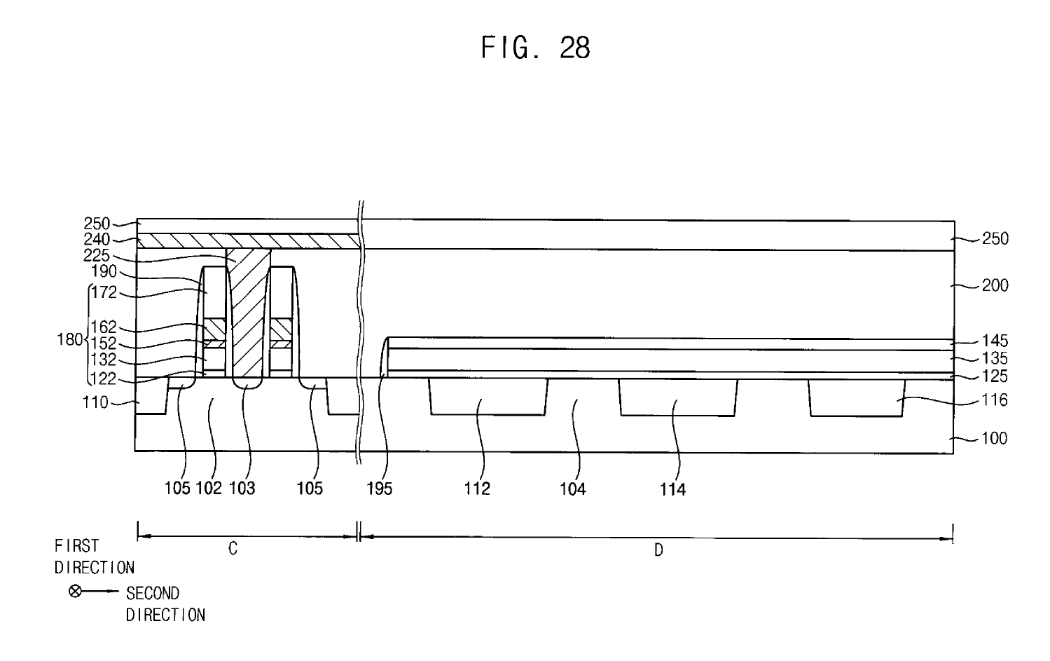

Referring to FIG. 28, a process substantially the same as or similar to that illustrated with reference to FIG. 7 may be performed. Thus, first and second spacers 190 and 195, respectively, may be formed on sidewalls of the first gate structures 180 and the first etch stop layer structure, respectively. A photoresist pattern (not illustrated) may be formed to cover the fourth region D, and an ion implantation process may be performed using the photoresist pattern, the first gate structures 180, and the first spacer 190 as an ion implantation mask to form first and second impurity regions 103 and 105, respectively, at upper portions of the first active region 102 of the substrate 100 adjacent to the first gate structures 180. A heat treatment process may be further performed on the substrate 100.

After removing the photoresist pattern, a first insulating interlayer 200 may be formed on the substrate 100 to cover the first gate structures 180, the first etch stop layer structure 111, the first spacer 190, and the second spacer 195.

After partially removing the first insulating interlayer 200 to form a first hole (not illustrated) exposing the first impurity region 103, a first contact plug 225 filling the first hole may be formed on the exposed first impurity region 103. A bit line 240 may be formed on the first insulating interlayer 200 to contact a top surface of the first contact plug 225. The bit line 240 may be formed to extend in the second direction.

A third insulating interlayer 250 may be formed on the first insulating interlayer 200 to cover the bit line 240.

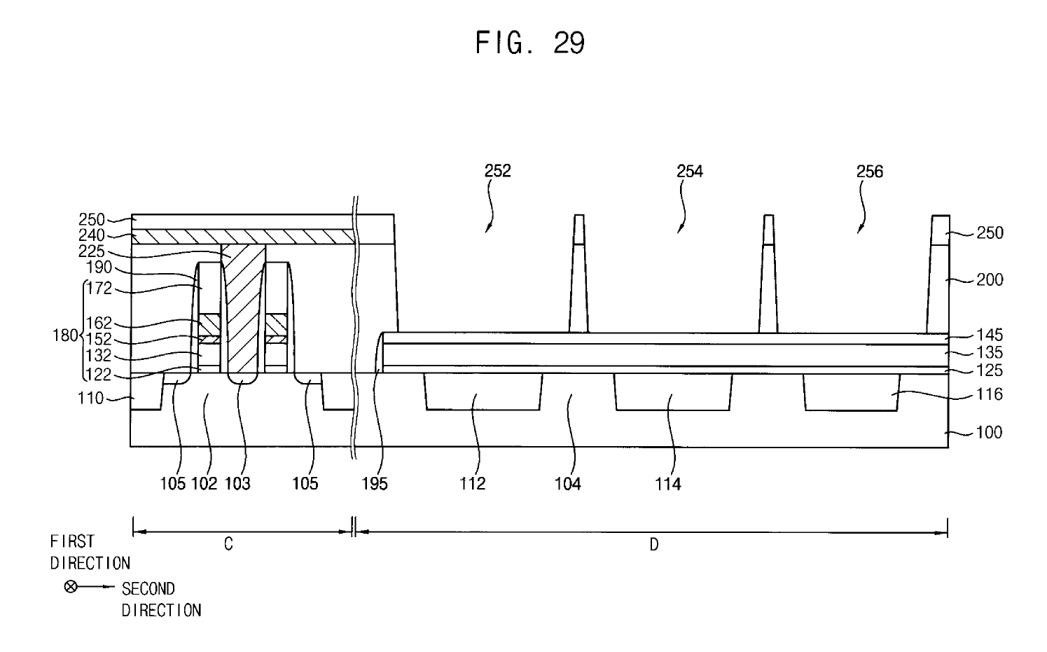

Referring to FIG. 29, a process substantially the same as or similar to that illustrated with reference to FIG. 8 may be performed.

Thus, the first and third insulating interlayers 200 and 250, respectively, may be partially removed to form third through fifth openings 252, 254, and 256, respectively, exposing the first etch stop layer structure 111.

The third through fifth openings 252, 254, and 256, respectively, may be formed to overlap the third to fifth isolation layer patterns 112, 114, and 116, respectively, and portions of the substrate 100 adjacent thereto, respectively.

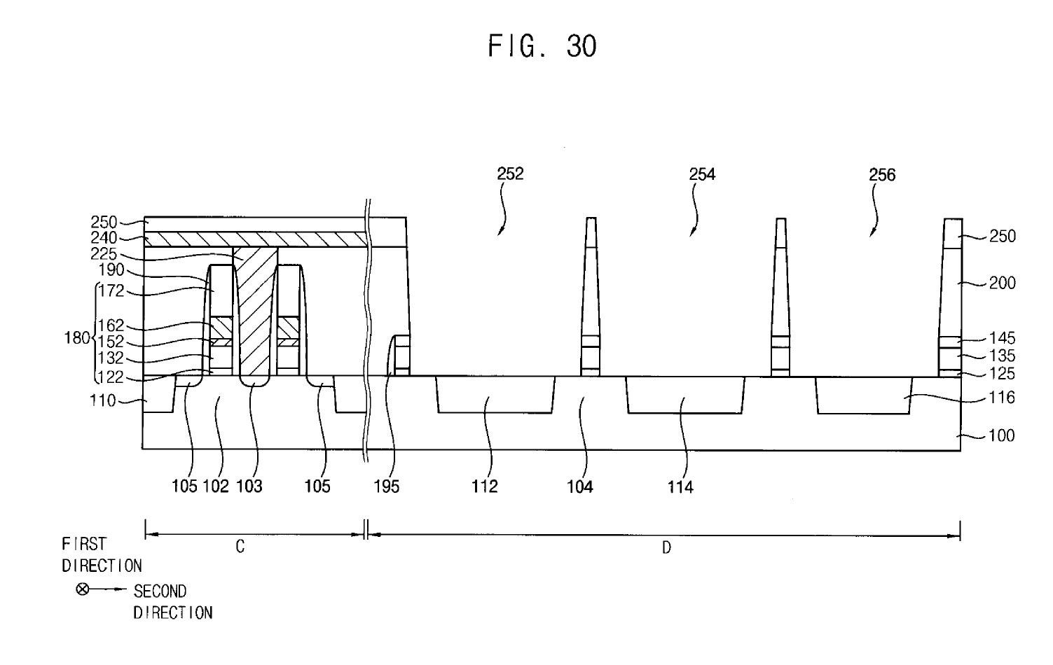

Referring to FIG. 30, processes substantially the same as or similar to those illustrated with reference to FIGS. 9 through 10 may be performed.

Thus, the second etch stop layer pattern 145 exposed by the third through fifth openings 252, 254, and 256, respectively, and the first etch stop layer pattern 135 and the insulation layer pattern 125 thereunder may be removed.

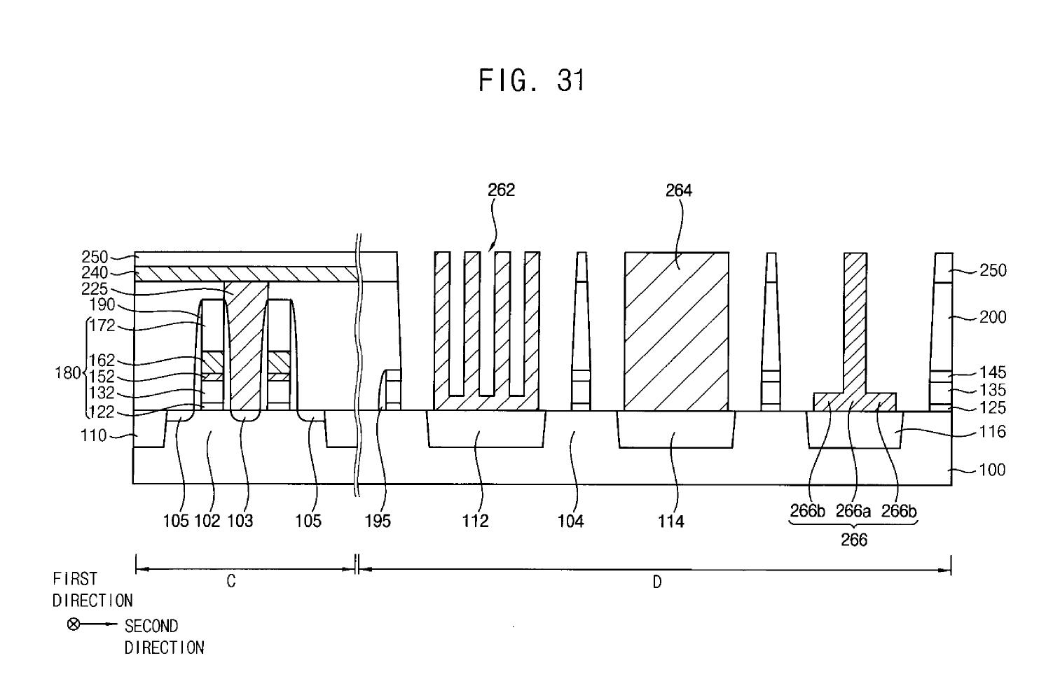

Referring to FIG. 31, processes substantially the same as or similar to those illustrated with reference to FIGS. 11 through 12 may be performed.

However, second through fourth semiconductor patterns 262, 264, and 266, respectively, may be formed on the substrate 100 in the fourth region D. Particularly, the second semiconductor pattern 262 may be formed on a central top surface of the third isolation layer pattern 112, the third semiconductor pattern 264 may be formed on a central top surface of the fourth isolation layer pattern 114, and the fourth semiconductor pattern 266 may be formed on a central top surface of the fifth isolation layer pattern 116.

The semiconductor pattern 262 may serve as a core of an optical coupler, the third semiconductor pattern 264 may serve as a core of a light waveguide, and the fourth semiconductor pattern 266 may serve as a core of a phase shifter. The second semiconductor pattern 262 may have a plurality of recesses at upper portions thereof, and the fourth semiconductor pattern 266 may include a protruding central portion 266a and flat edge portions 266b.

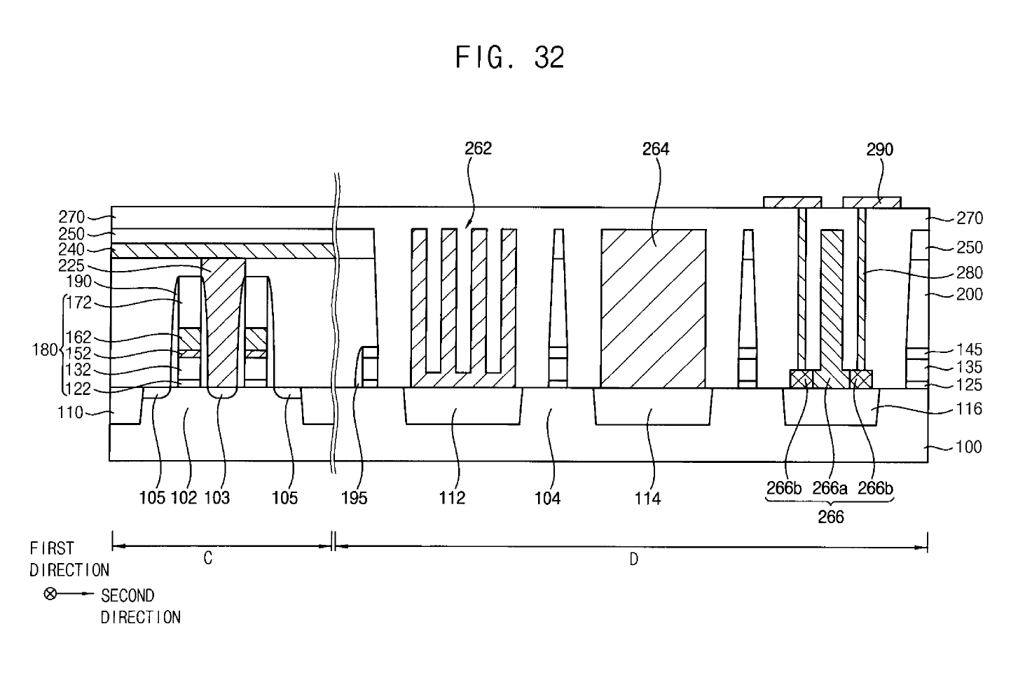

Referring to FIG. 32, a process substantially the same as or similar to that illustrated with reference to FIG. 2 may be performed.

Thus, a fourth insulating interlayer 270 may be formed on the substrate 100, the third through fifth isolation layer patterns 112, 114, and 116, respectively, the first insulating interlayer 200, and the third insulating interlayer 250 to sufficiently cover the second through fourth semiconductor patterns 262, 264, and 266, respectively.

The fourth insulating interlayer 270 may be partially removed to form second holes (not illustrated) exposing the edge portions 266b of the fourth semiconductor pattern 266, and impurities may be implanted into the exposed edge portions 266b. A third contact plug 280 filling each second hole may be formed, and electrodes 290 may be formed on the fourth insulating interlayer 270 to contact top surfaces of the third contact plugs 280.

Referring to FIG. 25, a fifth insulating interlayer 300 may be formed on the fourth insulating interlayer 270 to cover the electrodes 290, and a fourth etch stop layer pattern 320 and a capacitor 360 may be formed in the third region C. The capacitor 320 may be formed to include a lower electrode 320, a dielectric layer 330, and an upper electrode 350, and a method of forming the capacitor 320 may be applied herein.

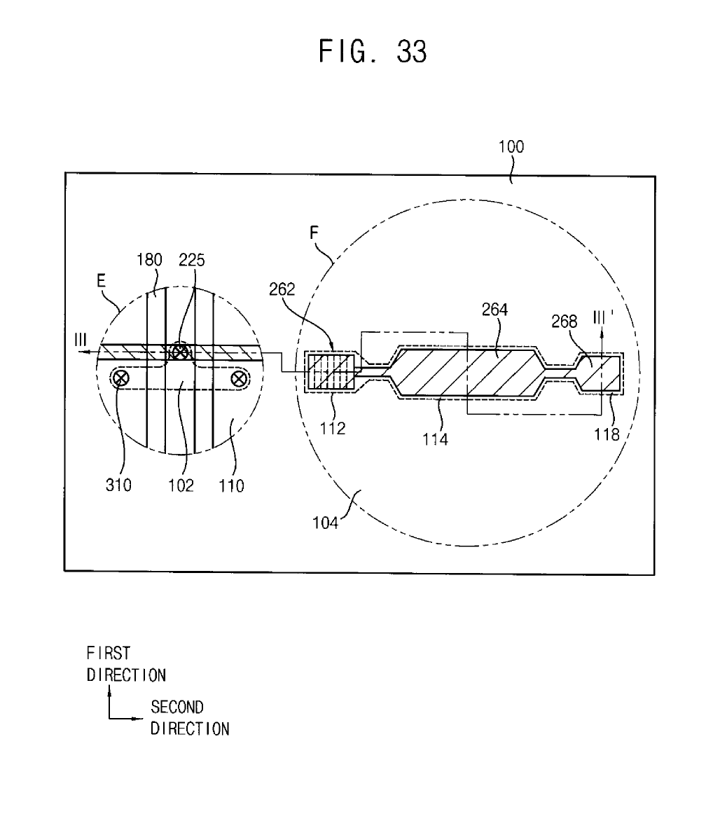

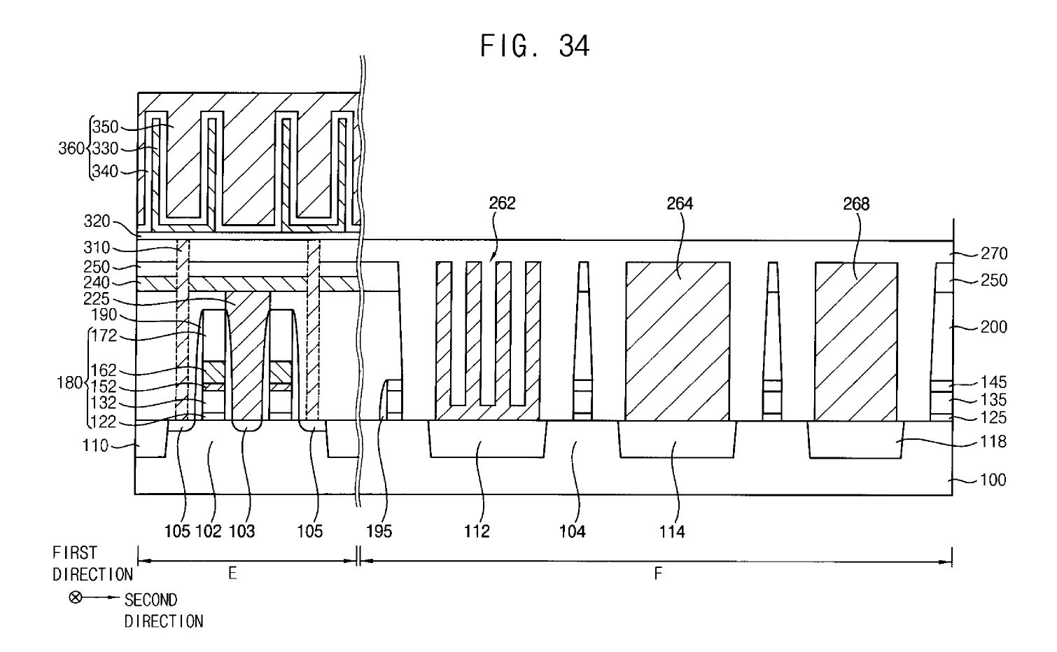

FIG. 33 is a plan view illustrating a semiconductor apparatus in accordance with an exemplary embodiment of the present general inventive concept, and FIG. 34 is a cross-sectional view of the semiconductor apparatus cut along the line III-III′ of FIG. 33. For the convenience of explanation, only some of the elements, such as a first gate structure 180, first and second active regions 102 and 104, respectively, second, third, and fifth semiconductor patterns 262, 264, and 268, respectively, are illustrated in FIG. 33. The semiconductor apparatus may be substantially the same as or similar to that illustrated with reference to FIGS. 24 and 25, except that the fifth semiconductor pattern 268 may be formed instead of the fourth semiconductor pattern 266. Thus, like reference numerals refer to like elements, and detailed explanations thereon are omitted herein.

Referring to FIGS. 33 and 34, the semiconductor apparatus may include a first gate structure 180, a bit line 240, a capacitor 360, semiconductor patterns 262, 264, and 268, respectively, and a first etch stop layer structure 111. The semiconductor apparatus may further include first and third through fifth insulating interlayers 200, 250, 270, and 300, respectively.

The substrate 100 may include a fifth region E and a sixth region F. First, third, fourth, and sixth isolation layer patterns 110, 112, 114, and 118, respectively, may be formed on the substrate 100. The first isolation layer pattern 110 may be formed on the substrate 100 in the fifth region E, and the third, fourth, and sixth isolation layer patterns 112, 114, and 118, respectively, may be formed on the substrate 100 in the sixth region F.

The second, third, and fifth semiconductor patterns 262, 264, and 268, respectively, may be formed on the third, fourth, and sixth isolation layer patterns 112, 114, and 118, respectively, in the sixth region F.

The second, third, and fifth semiconductor patterns 262, 264, and 268, respectively, may include single crystalline silicon or single crystalline germanium, but are not limited thereto. Top surfaces and sidewalls of the second, third, and fifth semiconductor patterns 262, 264, and 268, respectively, may be covered by the fourth insulating interlayer 270. The fifth semiconductor pattern 268 may include a first doping layer (not illustrated) doped with first impurities and a second doping layer (not illustrated) doped with second impurities.

In example embodiments of the present general inventive concept, the fifth semiconductor pattern 268 may serve as a photodiode.

The semiconductor apparatus and the method of manufacturing the same may be applied to various types of integrated circuits including both of electronic devices and optical devices.

Although a few embodiments of the present general inventive concept have been illustrated and described, it will be appreciated by those skilled in the art that changes may be made in these embodiments without departing from the principles and spirit of the present general inventive concept, the scope of which is defined in the appended claims and their equivalents.

What is claimed is:

1. A method of manufacturing a semiconductor apparatus, the method comprising:
forming a gate structure and an etch stop layer structure on a substrate including first and second regions, the gate structure being formed in the first region, and the etch stop layer structure being formed in the second region;
forming a first insulating interlayer on the substrate to cover the gate structure and the etch stop layer structure;
partially removing the first insulating interlayer to expose the etch stop layer structure;
removing the exposed etch stop layer to expose the substrate; and
forming an optical device on the exposed substrate.

2. The method of claim 1, wherein forming the gate structure and the etch stop layer structure includes:
sequentially forming an insulation layer and a first conductive layer on the substrate;
forming a second etch stop layer pattern on the first conductive layer in the second region;
forming a mask on the first conductive layer in the first region; and
patterning the first conductive layer and the insulation layer using the mask as an etching mask to form the gate structure and the etch stop layer structure, the gate structure including a gate insulation layer pattern, a gate electrode and the mask sequentially stacked on the substrate in the first region, and the etch stop layer structure including an insulation layer pattern, a first etch stop layer pattern and the second etch stop layer pattern sequentially stacked on the substrate in the second region.

3. The method of claim 2, wherein removing the exposed etch stop layer includes:
partially removing the first insulating interlayer to expose the second etch stop layer pattern; and
removing the exposed second etch stop layer pattern, the first etch stop layer pattern and the insulation layer pattern under the exposed second etch stop layer pattern to expose the substrate.

4. The method of claim 3, further comprising forming a second conductive layer structure on the first conductive layer and the second etch stop layer pattern before forming the mask,
wherein the mask is formed on the second conductive layer structure,
and wherein forming the gate structure in the first region includes patterning the second conductive layer structure, the first conductive layer, and the insulation layer using the mask as an etching mask.

5. The method of claim 4, wherein the first conductive layer is formed to include doped polysilicon, and the second conductive layer structure is formed to include a barrier layer and a metal layer sequentially stacked.

6. The method of claim 3, wherein the second etch stop layer pattern is formed to include a material having an etch selectivity with respect to the first conductive layer.

7. The method of claim 6, wherein the first conductive layer is formed to include doped polysilicon, and the second etch stop layer pattern is formed to include silicon oxide.

8. The method of claim 7, wherein the first insulating interlayer and the insulation layer are formed to include silicon oxide.

9. The method of claim 3, wherein the first conductive layer is formed to include a material having an etch selectivity with respect to the first insulating interlayer and the insulation layer.

10. The method of claim 3, wherein the second etch stop layer pattern is formed to include a material substantially the same as that of the insulation layer, and has a thickness equal to or greater than that of the insulation layer.

11. The method of claim 3, further comprising forming an isolation layer pattern on the substrate in the second region before forming the insulation layer and the first conductive layer on the substrate,
wherein removing the exposed second etch stop layer pattern, the first etch stop layer pattern and the insulation layer pattern under the exposed second etch stop layer pattern to expose the substrate includes exposing the isolation layer pattern and a portion of the substrate adjacent to the isolation layer pattern.

12. The method of claim 11, wherein forming the optical device includes performing an epitaxial growth process using the exposed substrate as a seed.

13. The method of claim 1, wherein forming the optical device includes:
performing the epitaxial growth process to form a semiconductor layer;
patterning the semiconductor layer to form a core partially exposing the isolation layer pattern; and
forming a second insulating interlayer to cover the core
and wherein the isolation layer pattern and the second insulating interlayer serve as a cladding surrounding the core, so that the core and the cladding form a light waveguide.

14. A semiconductor apparatus, comprising:
a gate structure including a gate insulation layer pattern, a gate electrode and a mask sequentially stacked on a substrate including an electronic device region and an optical device region, the gate structure being in the electronic device region;
an optical device on the substrate in the optical device region; and
an insulation layer pattern and an etch stop layer pattern sequentially stacked on the substrate adjacent to and spaced apart from the optical device,
wherein the gate insulation layer pattern and the insulation layer pattern include substantially the same material, and the gate electrode and the etch stop layer pattern includes substantially the same material.

15. The semiconductor apparatus of claim 14, wherein the gate electrode includes a doped polysilicon layer, a barrier layer and a metal layer sequentially stacked, wherein the etch stop layer pattern includes doped polysilicon, and wherein the gate insulation layer pattern and the insulation layer pattern include silicon oxide.

16. A semiconductor apparatus, comprising:
a substrate having at least a first region and a second region;
an electrical device disposed in the first region;
an optical device disposed in the second region; and
an etch stop layer structure disposed in the second region apart from the optical device.

17. The semiconductor apparatus of claim 16, wherein:
the electrical device comprises a gate structure; and
the optical device comprises a core and a cladding.

18. The semiconductor apparatus of claim 17, wherein the core, the gate structure, and the etch stop layer structure are all disposed on the substrate.

19. The semiconductor apparatus of claim 17, wherein the cladding comprises:
an isolation layer pattern disposed between the core and the substrate; and
an insulating interlayer to surround portions of the core not in contact with the isolation layer pattern.

20. The semiconductor apparatus of claim 16, wherein the etch stop layer structure comprises:
an insulation layer pattern disposed on the substrate;
a first etch stop layer disposed on the insulation layer pattern; and
a second etch stop layer disposed on the insulation layer pattern.
